(19) United States
(12) Patent Application Publication
(10) Pub. No.: US 2013/0203268 A1
(43) Pub. Date: Aug. 8, 2013

(54) FILM DEPOSITION APPARATUS AND FILM DEPOSITION METHOD

(71) Applicant: Tokyo Electron Limited, Tokyo (JP)

(72) Inventors: Hitoshi KATO, Iwate (JP); Shigehiro MIURA, Iwate (JP)

(73) Assignee: Tokyo Electron Limited, Tokyo (JP)

(21) Appl. No.: 13/753,626

(22) Filed: Jan. 30, 2013

(30) Foreign Application Priority Data
Feb. 2, 2012 (JP) 2012-020992

(51) Int. Cl. H01L 21/02

(52) U.S. Cl. CPC H01L 21/02263
USPC 438/778; 118/719

(57) ABSTRACT

A disclosed film deposition apparatus has a separation area arranged between a first process area and a second area as viewed from a wafer that is rotated by a turntable, and a modification area arranged between the second process area and the first process area as viewed from the wafer that is rotated by the turntable where a modification process is performed on a reaction product formed on the wafer by a plasma generating unit. Further, a protruding portion is arranged at a casing that surrounds the modification area, and the atmospheric pressure of the modification area is arranged to be higher than the atmospheric pressure of the areas adjacent to the modification area.

### CROSS-REFERENCE TO RELATED APPLICATIONS

This patent application is based upon and claims the benefit of priority of Japanese Patent Application No. 2012-020992 filed on Feb. 2, 2012, the entire contents of which are incorporated herein by reference.

### BACKGROUND OF THE INVENTION

1. Field of the Invention

The present invention relates to a film deposition apparatus and a film deposition method that involve forming a reaction product on the surface of a substrate by sequentially supplying mutually reactive process gases and performing a plasma process on the substrate.

2. Description of the Related Art

The Atomic Layer Deposition (ALD) method is one known method for forming a thin film such as a silicon nitride (Si—N) film on a substrate such as a semiconductor wafer (simply referred to as “wafer” hereinafter). For example, Patent Document 1 discloses a film deposition apparatus using the ALD method. In the disclosed apparatus, plural sheets of wafers are arranged in peripheral directions on a turntable provided in a vacuum chamber, and plural gas supply nozzles are arranged to face the turntable. The disclosed apparatus includes a separation area for supplying a separation gas that is arranged between process areas for supplying the process gases from the gas supply nozzles so that the process gases may be prevented from mixing with one another.

Also, Patent Document 2 discloses arranging a plasma area along the peripheral direction of the turntable in addition to the process areas and the separation area. In the plasma area, plasma is used to modify a reaction product or activate the process gases, for example. However, when attempts are made to miniaturize the apparatus, it becomes difficult to secure adequate space for arranging the plasma area in the apparatus. In other words, a size increase of the apparatus becomes inevitable when the plasma area is arranged in the apparatus. Also, when the plasma area is arranged, a plasma generating gas needs to be supplied to the plasma area so that operation costs of the apparatus (cost of gas) may be increased and the size of the vacuum pump may have to be increased.
[Patent Document 1] Japanese Laid-open Patent Publication No. 2010-239102
[Patent Document 2] Japanese Laid-open Patent Publication No. 2011-40574

### SUMMARY OF THE INVENTION

It is a general object of at least one embodiment of the present invention to provide a film deposition apparatus and a film deposition method that substantially obviate one or more problems caused by the limitations and disadvantages of the related art. It is one particular object of at least one embodiment of the present invention to reduce the size of a vacuum chamber while preventing process gases from mixing with each other within the vacuum chamber in a film deposition apparatus that forms a film on a substrate by sequentially supplying mutually reactive process gases and performing a plasma process on the substrate.

According to one embodiment of the present invention, a film deposition apparatus is provided that forms a film on a substrate by repeatedly performing a process of sequentially supplying a first process gas and a second process gas that react with one another inside a vacuum chamber. The film deposition apparatus includes a turntable arranged inside the vacuum chamber and including a substrate mounting area that is formed on the surface of the turntable for mounting a substrate, the turntable being configured to rotate the substrate mounting area. The film deposition apparatus also includes a first process area and a second process area that are separated from each other with respect to the peripheral direction of the turntable, a first process gas supplying unit that supplies the first process gas that is adsorbed on a surface of the substrate to the first process area, a second process gas supplying unit that supplies the second process gas to the second process area to cause a reaction with components of the first process gas adsorbed on the surface of the substrate and form a reaction product on the substrate, a separation area positioned between the first process area and the second process area as viewed from an upstream side of a rotational direction of the turntable, a separation gas supplying unit that supplies a separation gas to the separation area to separate a first atmosphere of the first process area from a second atmosphere of the second process area, and a modification area for performing a modification process on the reaction product on the substrate using plasma. The modification area is positioned between the second process area and the first area as viewed from the upstream side of the rotational direction of the turntable and is arranged between the turntable and a ceiling wall portion that faces the surface of the turntable.

The film deposition apparatus further includes a modification gas supplying unit that supplies a modification gas that does not react with the first process gas and the second process gas to the modification area, a first plasma generating unit that generates plasma from the modification gas, and a narrow space forming portion that has an end portion that defines a narrow space formed between the end portion and the turntable. The narrow space forming portion is positioned between the modification area and an adjacent area adjacent to the modification area with respect to the peripheral direction of the turntable and has its end portion positioned lower than the ceiling wall portion and the ceiling face of the adjacent area to prevent gas at the adjacent area from intruding into the modification area. The pressure at the modification area is arranged to be higher than the pressure at the adjacent area, and the modification area is arranged to act as a separation area for preventing the first process gas and the second process gas from mixing with one another.

According to another embodiment of the present invention, a film deposition method is provided for forming a film on a substrate by repeatedly performing a process of sequentially supplying a first process gas and a second process gas that react with one another inside a vacuum chamber. The film deposition method includes the steps of mounting a substrate on the surface of a turntable that is arranged inside the vacuum chamber and rotating the substrate by rotating the turntable, supplying a first process gas that is adsorbed on the surface of the substrate to a first process area, and supplying a second process gas to a second process area to cause a reaction with components of the first process gas adsorbed on the surface of the substrate and form a reaction product on the substrate. The second process area is separated from the first process area with respect to a peripheral direction of the turntable. The film deposition method further includes the steps of supplying a separation gas to a separation area positioned between the first process area and the second process area as viewed from an upstream side of a rotational direction of the turntable and separating a first atmosphere of the first process area from a second atmosphere of the second process area, and supplying a modification gas that does not react with the first process gas and the second process gas to a modification area for performing a modification process on the reaction product on the substrate using plasma. The modification area is positioned between the second process area and the first area as viewed from the upstream side of the rotational direction of the turntable and is arranged between the turntable and a ceiling wall portion that faces the surface of the turntable. The film deposition method further includes the steps of generating the plasma from the modification gas and modifying the reaction product on the substrate, and preventing a gas at an adjacent area adjacent to the modification area with respect to the peripheral direction from intruding into the modification area by a narrow space forming portion that has an end portion that defines a narrow space formed between the end portion and the turntable. The narrow space forming portion is positioned between the modification area and the adjacent area and its end portion is positioned lower than the ceiling wall portion and a ceiling face of the adjacent area. The pressure at the modification area is arranged to be higher than the pressure at the adjacent area, and the modification area is arranged to act as a separation area for preventing the first process gas and the second process gas from mixing with one another.

### BRIEF DESCRIPTION OF THE DRAWINGS

FIG. 1 is a vertical cross-sectional view illustrating an exemplary film deposition apparatus according to an embodiment of the present invention;

FIG. 2 is a perspective view of the film deposition apparatus;

FIG. 3 is a cross-sectional plan view of the film deposition apparatus;

FIG. 4 is another cross-sectional plan view of the film deposition apparatus;

FIG. 5 is a perspective view of a part of the interior of the film deposition apparatus;

FIGS. 6A-6B are vertical cross-sectional views of a part of the interior of the film deposition apparatus;

FIG. 7 is an exploded perspective view of a part of the interior of the film deposition apparatus;

FIG. 8 is a vertical cross-sectional view of a part of the interior of the film deposition apparatus;

FIG. 9 is a perspective view of a housing of the film deposition apparatus

FIG. 10 is a perspective view of slits of a Faraday shield of the film deposition apparatus;

FIG. 11 is a plan view of the Faraday shield of the film deposition apparatus;

FIG. 12 is an exploded perspective view of a side ring of the film deposition apparatus;

FIG. 13 is a vertical cross-sectional view of a part of a labyrinth structure of the film deposition apparatus;

FIG. 14 is a horizontal cross-sectional view of the film deposition apparatus schematically illustrating gas flows inside the film deposition apparatus;

FIG. 15 schematically illustrates generation of plasma in the film deposition apparatus;

FIG. 16 is a vertical cross-sectional view of a part of another exemplary film deposition apparatus;

FIGS. 17A and 17B are vertical cross-sectional views of parts of another exemplary film deposition apparatus;

FIG. 18 is a plan view of a part of another exemplary film deposition apparatus;

FIG. 19 is a perspective view of a part of another exemplary film deposition apparatus;

FIG. 20 is a plan view of a part of another exemplary film deposition apparatus;

FIG. 21 is a plan view of a part of another exemplary film deposition apparatus;

FIG. 22 is a plan view of a part of another exemplary film deposition apparatus;

FIG. 23 is a plan view of a part of another exemplary film deposition apparatus;

FIG. 24 is a vertical cross-sectional view of a part of another exemplary film deposition apparatus;

FIG. 25 is a characteristic diagram illustrating simulation results obtained by the embodiment;

FIG. 26 is another characteristic diagram illustrating simulation results obtained by the embodiment;

FIG. 27 is another characteristic diagram illustrating simulation results obtained by the embodiment;

FIG. 28 is another characteristic diagram illustrating simulation results obtained by the embodiment;

FIG. 29 is another characteristic diagram illustrating simulation results obtained by the embodiment;

FIG. 30 is another characteristic diagram illustrating simulation results obtained by the embodiment;

FIG. 31 is another characteristic diagram illustrating simulation results obtained by the embodiment;

FIG. 32 is another characteristic diagram illustrating simulation results obtained by the embodiment;

FIG. 33 is another characteristic diagram illustrating simulation results obtained by the embodiment;

FIG. 34 is another characteristic diagram illustrating simulation results obtained by the embodiment;

FIG. 35 is another characteristic diagram illustrating simulation results obtained by the embodiment; and

FIG. 36 is another characteristic diagram illustrating simulation results obtained by the embodiment.

### DETAILED DESCRIPTION OF THE PREFERRED EMBODIMENTS

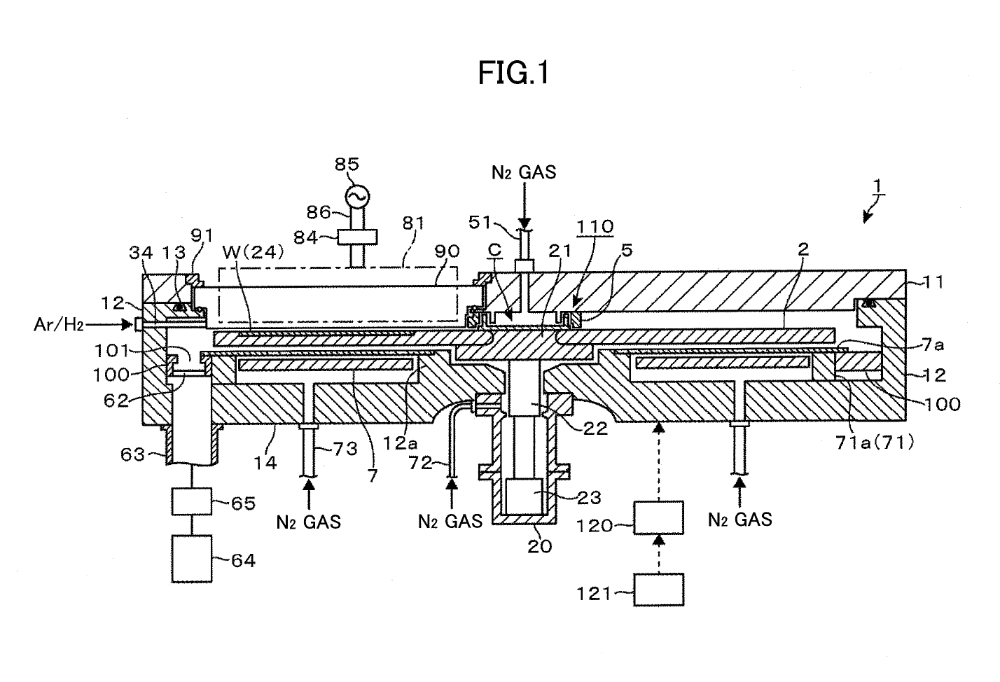

In the following, a film deposition apparatus according to an embodiment of the present invention is described with reference to FIGS. 1-13. Referring to FIGS. 1-4, the film deposition apparatus of the present embodiment includes a vacuum chamber 1 that is substantially in a circular shape in its plan view and a turntable 2 corresponding to a loading table accommodated inside the vacuum chamber 1 that is configured to rotate around a rotational center positioned at the center of the vacuum chamber 1. As is described in detail below, each time the turntable 2 turns (rotates), the film deposition apparatus performs a Si-containing gas adsorption process on the surface of a wafer W, a nitriding process on components of the Si-containing gas adsorbed on the wafer W, and a plasma modification process on the silicon nitride film formed on the wafer W. In arranging units such as nozzles for realizing the above processes in the film deposition, accommodations are made to prevent process gases used in the adsorption process and the nitriding process from mixing with each other in the vacuum chamber 1 while maintaining the dimensions of the vacuum chamber 1 in plan view as small as possible. Next, various component parts of the film deposition apparatus are described in detail.

The vacuum chamber 1 includes a ceiling plate 11 and a chamber body 12. The ceiling plate 11 is configured to be attachable to or detachable from the chamber body 12. The diameter (inner diameter) of the vacuum chamber 1 in plan view is arranged to be about 1100 mm, for example. A separation gas supplying pipe 51 is connected to a center portion on an upper face side of the ceiling plate 11. A separation gas such as a nitrogen gas (N₂ gas) is supplied from the separation gas supplying pipe 51 to prevent different gases from mixing in a center area C inside the vacuum chamber 1. Referring to FIG. 1, reference symbol 13 provided along a peripheral portion on an upper surface of the chamber body 12 is a sealing member. The sealing member 13 is, for example, an O ring.

A center portion of a turntable 2 is fixed to a core portion 21 that is substantially in a cylindrical shape. A rotational shaft 22 extending in a vertical direction is connected to the lower surface of the core portion 21. The turntable 2 is freely rotatable in a clockwise direction around a vertical axis of the rotational shaft. The diameter of the turntable 2 is arranged to be about 1000 mm, for example. Referring to FIG. 1, a driving mechanism 23 is provided to rotate the rotational shaft 22 around the vertical axis, and a case body 20 accommodates the rotational shaft 22 and the driving mechanism 23. An upper flange portion of the case body 20 is hermetically attached to a lower surface of the bottom portion 14 of the vacuum chamber 1. A purge gas supplying pipe 72 is connected to a lower area of the turntable 2 so as to supply N₂ gas as a purge gas. A ring-shaped protruding portion 12a of the bottom portion 14 of the vacuum chamber 1 surrounds the core portion 21. The ring-shaped protruding portion 12a is shaped like a ring and approaches the lower surface of the turntable 2.

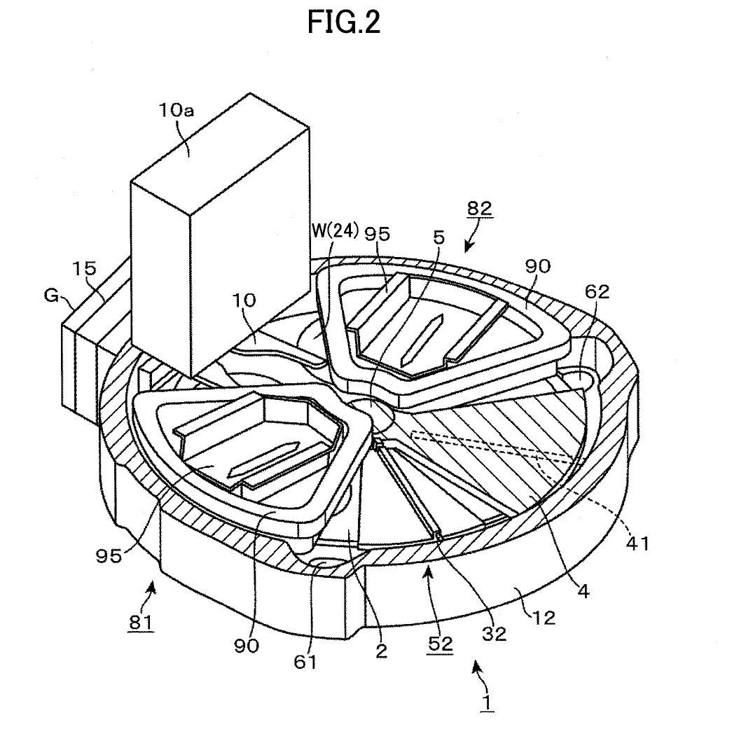

Referring to FIGS. 2-4, circular concave portions 24 are provided on the surface of the turntable 2 along rotational directions (peripheral directions). The wafers W having a diameter of 300 mm, for example, are mounted on the circular concave portions 24. The circular concave portion 24 is designed to have a diameter and a depth so that the surfaces of the wafers W and the surface of the turntable 2 (where the wafers W are not mounted) come level with each other when the wafers W are dropped or accommodated into the circular concave portions 24. Through holes (not shown) through which lift pins (described below) penetrate are provided on the bottom faces of the circular concave portions 24. The lift pins cause the wafers to be pushed up so that the wafers are moved up or down. The number of the lift pins may be three, for example.

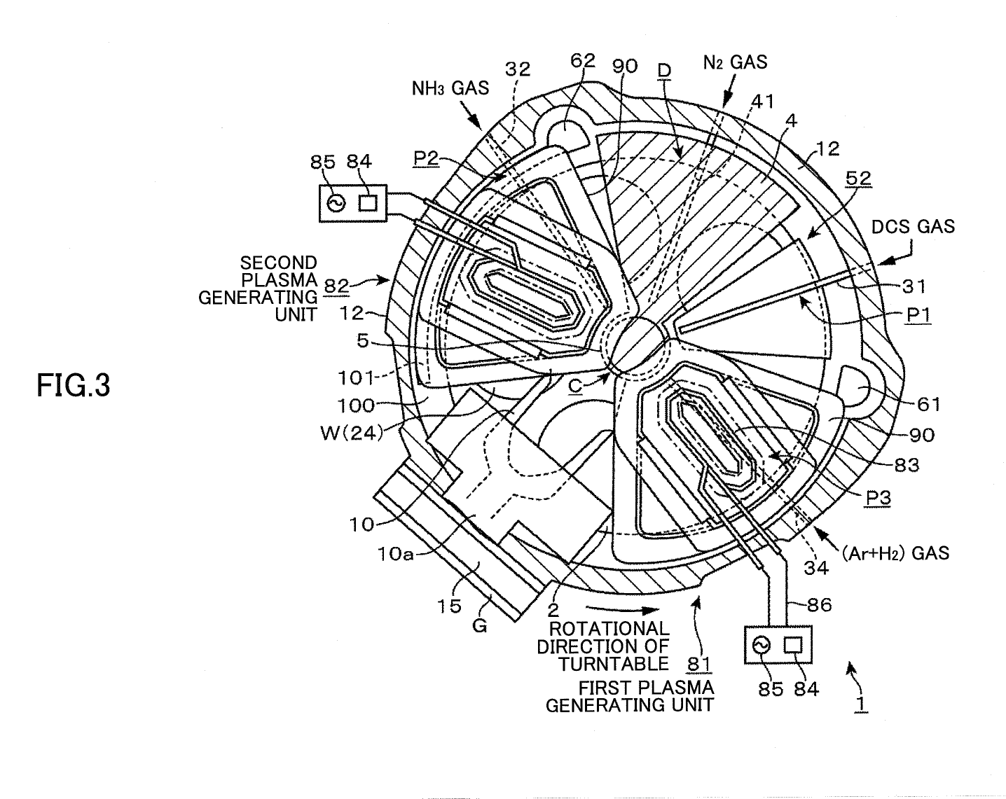

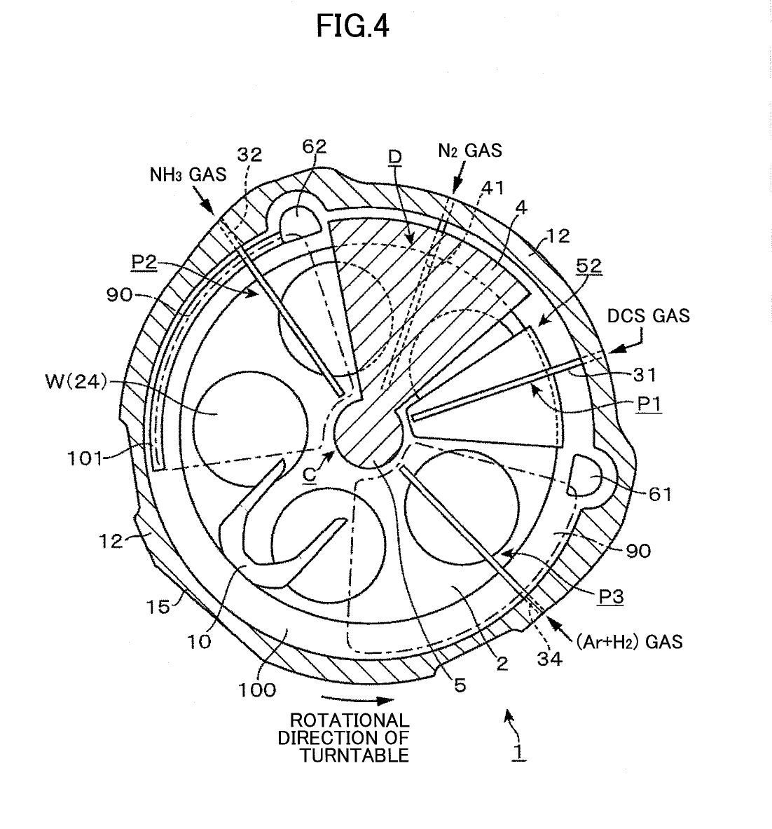

Referring to FIGS. 3-4, four nozzles 31, 32, 34, and 41 made of quartz, for example, are arranged radially in peripheral directions of the vacuum chamber 1. The nozzles 31, 32, 34, and 41 face the passing regions of the circular concave portions 24 when the turntable 2 having the circular concave portions 24 is rotated. These nozzles 31, 32, 34, and 41 are attached to an outer peripheral wall of the vacuum chamber 1 toward the center area C so as to horizontally extend toward the center area C while facing the wafers W. In the illustrated example, the nozzles 34, 31, 41, and 32 as a first plasma generating gas nozzle 34, a first process gas nozzle 31, a separation gas nozzle 41, and a second plasma generating gas nozzle 32 that also acts as a second process gas nozzle are arranged in this order in a counter-clockwise direction (rotational direction of the turntable 2) from a transfer opening 15 (described below).

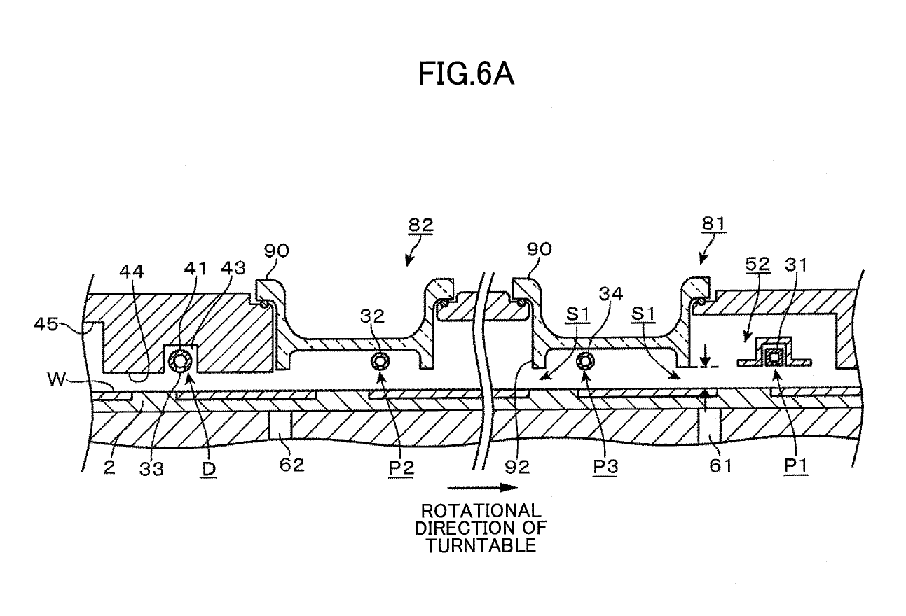

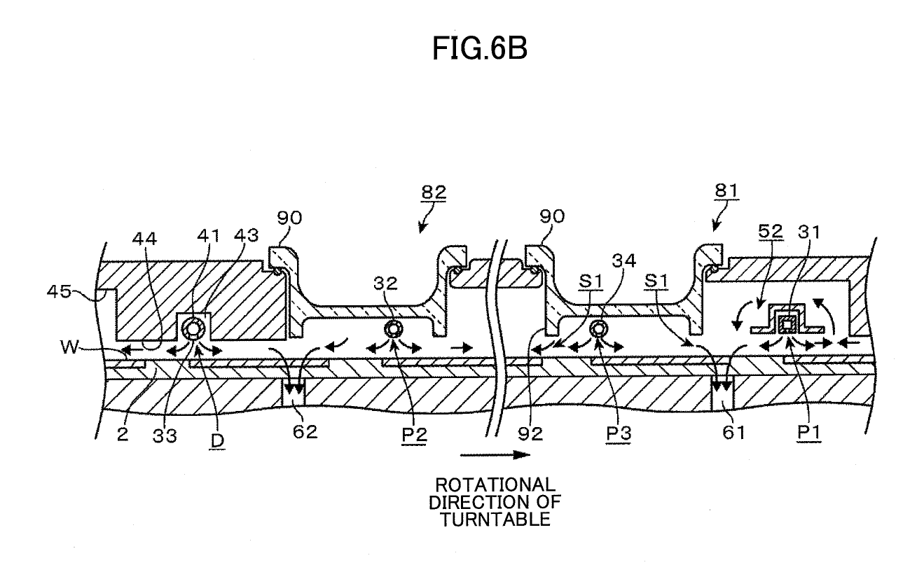

As is shown in FIGS. 6A-6B, the portion of the first process gas nozzle 31 that is positioned towards the center area C side from the outer peripheral edge of the turntable 2 is arranged into an angular tube shape so as to prevent gas from coming around between the first process gas nozzle 31 and a cover body 53, which is described below.

Referring to FIG. 3, a first plasma generating unit 81 and a second plasma generating unit 82 are respectively arranged at the upper sides of the first plasma generating gas nozzle 34 and the second plasma generating gas nozzle 32. The first plasma generating unit 81 and the second plasma generating unit 82 are configured to convert the gases discharged from the first plasma generating gas nozzle 34 and the second plasma generating gas nozzle 32 into plasma. The first and second plasma generating units 81 and 82 are described in detail below. It is noted that in FIG. 4, the plasma generating units 81, 82, and a casing 90 are omitted so that the plasma generating gas nozzles 32, 34 may be viewed. In FIG. 3, the plasma generating unit 81, 82 and the casing 90 are attached. Also, it is noted that in FIGS. 2-4, the ceiling plate 11 is omitted.

In the present embodiment, the first process gas nozzle 31 acts as a first process gas supplying unit, and the second plasma generating gas nozzle 32 acts as a second process gas supplying unit. The first plasma generating gas nozzle 34 acts as a modification gas supply unit. The separation gas nozzle 41 acts as a separation gas supply unit. It is noted that in FIG. 1, the plasma generating unit 81 is schematically illustrated by a dashed-dotted line.

The nozzles 31, 32, 34, 41, and 42 are connected to corresponding gas supply sources (not shown) via corresponding flow rate controlling valves. For example, the first process gas nozzle 31 may be connected to a gas supply source for supplying a first process gas containing silicon (Si) such as DCS (dichlorosilane) gas. The first plasma generating gas nozzle 34 may be connected to a gas supply source for supplying a modification gas made of a mixed gas containing Argon (Ar) gas and hydrogen (H₂) gas, for example. The second plasma generating gas nozzle 32 may be connected to a gas supply source for supplying a gas that is used as a second process gas and a second plasma generating gas such as ammonia (NH₃) gas. The separation gas nozzle 41 may be connected to a gas supply source for supplying a separation gas such as nitrogen (N₂) gas. It is noted that other examples, ammonia gas may be supplied along with argon gas corresponding the plasma generating gas, or a gas containing a nitrogen element (N) such as nitrogen (N₂) gas may be supplied instead of ammonia gas.

Plural gas ejection holes 33 for supplying gas to the wafer W are formed on the lower sides of the gas nozzles 31, 32, 34, and 41 along the radial directions of the turntable 2 (see FIGS. 6A-6B). The plural gas ejection holes 33 may be arranged at equal intervals along the gas nozzles 31, 32, 34, and 41, for example. These nozzles 31, 32, 34, 41 and 42 are arranged over the turntable 2 such that a distance between the lower sides of the nozzles 31, 32, 34, 41 and 42 and the upper surface of the turntable 2 is, for example, about 1-5 mm.

As is shown in FIG. 4, an area at the lower side of the process gas nozzles 31 corresponds to a first process area P1 for causing the wafers W to adsorb the Si-containing gas, and an area at the lower side of the second plasma generating gas nozzle 32 corresponds to a second process area P2 where components of the Si-containing gas adsorbed on the wafers W are reacted with the plasma of ammonia gas. An area at the lower side of the first plasma generating gas nozzle 34 corresponds to a third process area P3 where a modification process is performed for modifying the reaction product formed on the wafers W by passing the process areas P1 and P2. The process area P3 also separates the first process area P1 and the second process area P2. The separation gas nozzle 41 forms a separating area D for separating the first process area P1 and the second process area P2. That is, the separation gas nozzle 41 is arranged between the first process area P1 and the second process area P2 as viewed from the upstream side of the rotational direction of the turntable 2. The third process area P3 is similarly arranged between the first process area P1 and the second process area P2 as viewed from the upstream side of the rotational direction of the turntable 2.

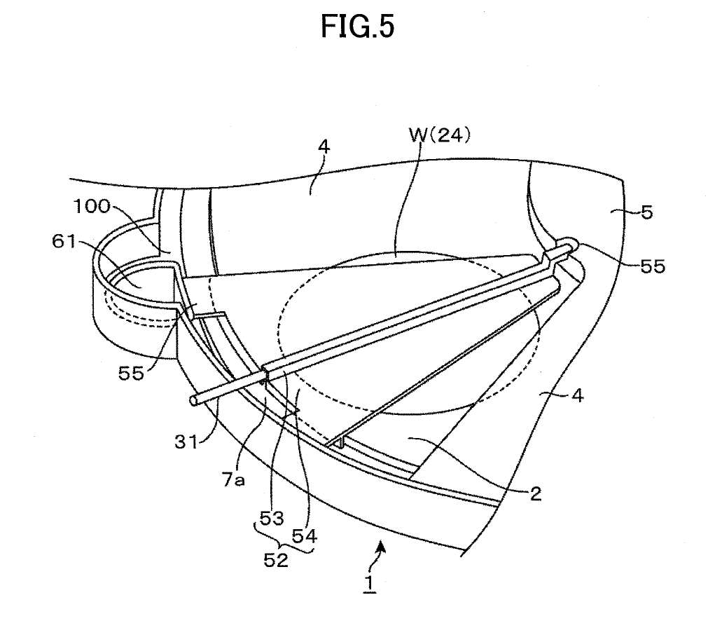

As is shown in FIG. 5, a nozzle cover (fin) 52 is arranged at the upper side of the first process gas nozzle 31. The nozzle cover 52 may be made of quartz, for example, and covers the first process gas nozzle 31 along its longitudinal direction. The nozzle cover 52 is arranged so that the first process gas flows across the wafers W while the separation gas and the argon gas flow towards the ceiling plate 11 side of the vacuum chamber 1 and is prevented from flowing in the vicinity of the wafers W. The nozzle cover 52 includes the cover body 53 that is arranged into a box-shape with an opening at the bottom side for accommodating the first process gas nozzle 31. The nozzle cover 52 also includes rectifying plates 54 that are connected to the edges of the bottom side opening of cover body 53 at the upstream side and downstream side of the rotational direction of the turntable 2. The side wall faces (vertical faces) of the cover body 53 at the rotational center side of the turntable 2 are arranged to face the tip portion of the first process gas nozzle 31 and extend toward the turntable 2. The side wall faces of the cover body 53 at the outer edge side of the turntable 2 are cutout to avoid interference with the first process gas nozzle 31. Accordingly, a narrow gap is formed along the peripheral directions between the side wall faces of the cover body 35 and the turntable 2 as viewed from the first process gas nozzle.

The areas of the rectifying plates 54 that are positioned towards the inner wall face of the vacuum chamber 1 from the outer peripheral edge of the turntable 2 are arranged to bend towards the lower side along the outer peripheral edge of the turntable 2 in order to prevent dilution of the first process gas at the tip portion side of the first process gas nozzle 31 by the separation gas that is supplied to the center area C. The cover body 53 has support portions 55 arranged at the longitudinal direction ends of the first process gas nozzle 31, and the support portions 55 are supported by a protruding portion 5 and a cover member 7a, which are described in detail below.

As is shown in FIGS. 3-4, the ceiling plate 11 of the vacuum chamber 1 at the separation area D has a convex portion 4 arranged into a fan-like shape having a groove portion 43. The separation gas nozzle 41 is accommodated in the groove portion 43.

As is shown in FIGS. 6A-6B, a ceiling surface 44 is formed on both sides of the separation gas nozzle 41 along the peripheral direction of the turntable 2 to prevent the process gases from mixing with one another. The ceiling surface 44 (first ceiling surface 44) is one of lower surfaces of the convex portion 4. The convex portion 4 also has a second ceiling surface 45 which is another one of the lower surfaces of the convex portion 4 that is positioned above the first ceiling surface 44. A peripheral portion of the convex portion 4 (a portion on a side of an outer edge of a vacuum chamber 1) faces the outer edge surface of the turntable 2 and is held slightly apart from the chamber body 12. The peripheral portion of the convex portion 4 is bent in a shape like an “L” so as to prevent the process gases from mixing. It is noted that FIGS. 6A and 6B are vertical cross-sectional views of the vacuum chamber 1 across the peripheral directions of the turntable 2.

Next, the first plasma generating unit 81 and the second plasma generating unit 82 are described in detail. The first plasma generating unit 81, which is arranged at the right side of the transfer opening 15 (turntable 2 rotational direction downstream side), is formed by winding an antenna 83 made of metal in a coil-like shape (see FIG. 3). In this example, the antenna 83 is made of a material formed by laminating a nickel plating and a gold plating on a copper (Cu) surface in this order. Also, the antenna 83 is arranged on the ceiling plate 11 of the vacuum chamber 1 so that the antenna 83 may be hermetically separated from an internal area of the vacuum chamber 1.

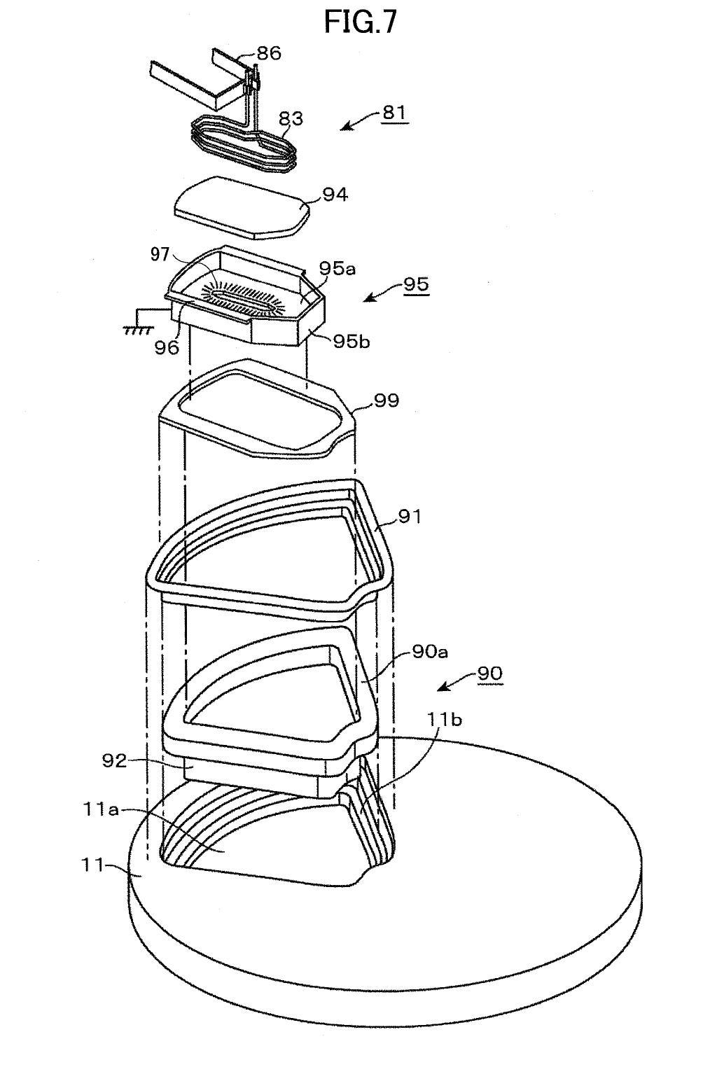

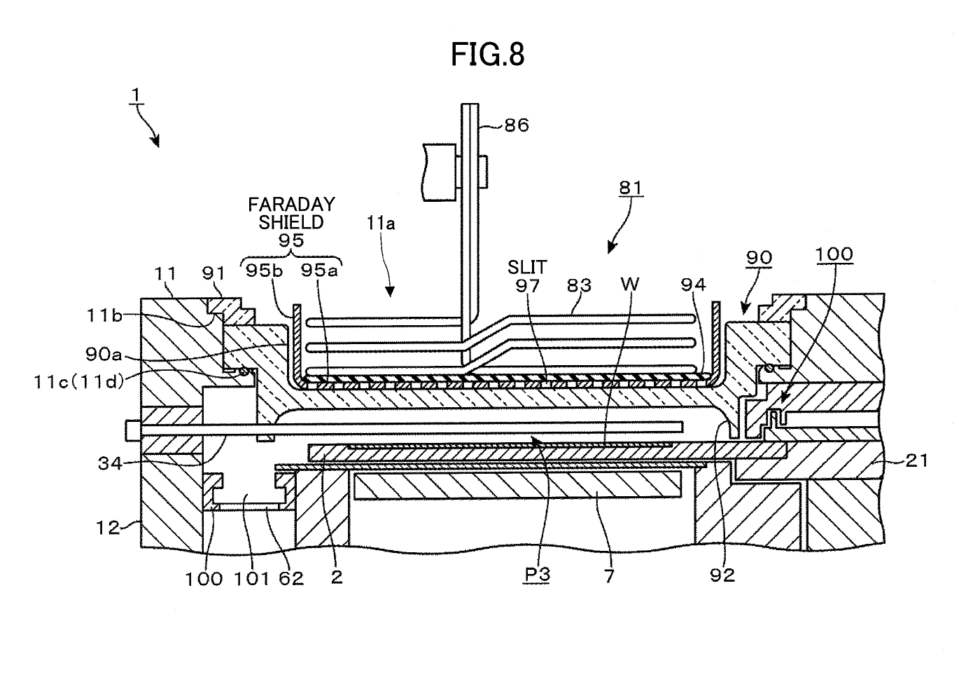

As is shown in FIGS. 7-8, the ceiling plate 11 has an opening portion 11a arranged into a fan-like shape in its plan view. The opening portion 11a is arranged at a position above the plasma generating gas nozzle 34, between a position slightly downstream of the plasma generating gas nozzle 34 with respect to the rotational direction of the turntable 2 and a position slightly towards the plasma generating gas nozzle 34 from the position of the transfer opening 15. It is noted that although the plasma generating units 81 and 82 are referred to as “first plasma generating unit 81” and “second plasma generating unit 82” to prevent confusion between the two, the plasma generating units 81 and 82 have substantially the same configuration and are each configured to perform plasma processes independently.

The opening portion 11a may extend in the radial direction from a position about 60 mm towards the outer periphery from the rotational center of the turntable 2 and a position about 80 mm outward from the outer peripheral edge of the turntable 2. Further, in order to prevent interference with a labyrinth structure 110, which is arranged at the center area C of the vacuum chamber 1, the opening portion 11a is recessed like an arc so that an end of the opening portion 11a at the center side of the turntable 2 faces an outer edge of the labyrinth structure 110.

As is shown in FIGS. 7-8, the opening portion 11a is formed by three step portions lib so that the diameter of the opening portion 11a gradually decreases from an upper face side of the ceiling plate 11 to a lower face side. A groove 11c is arranged to extend in the peripheral direction on the upper face of the lowermost step portion 11b among the step portions 11b, and a sealing member such as an O ring 11d is accommodated inside the groove 11c. It is noted that the groove 11c and the O ring 11d are omitted in FIG. 7.

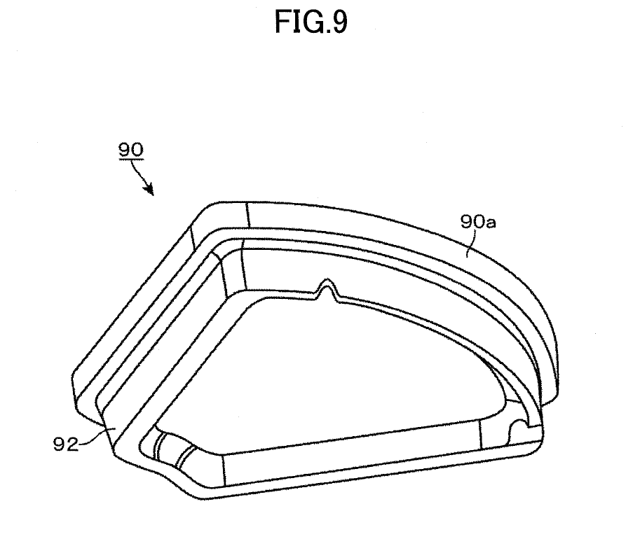

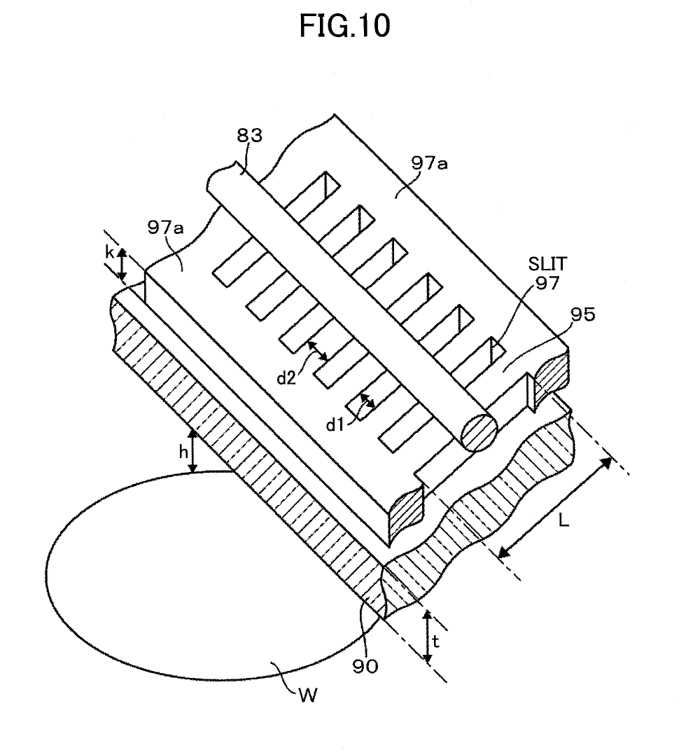

As is shown in FIGS. 7 and 9, the casing 90 is fit into the opening portion 11a so that the antenna 83 may be positioned below the ceiling plate 11. Specifically, the casing 90 has a flange portion 90a extending in the peripheral direction at the upper side and protruding outward in the horizontal direction so that the outer periphery of the flange portion 90a is greater than the outer periphery of the center portion of the casing 90. The casing 90 is made of a material permeable to magnetic force (dielectric material) such as quartz for enabling a magnetic field generated by the first plasma generating unit 81 to reach inside the vacuum chamber 1. Referring to FIG. 10, the thickness t of the center portion of the casing 90 may be 20 mm, for example. Further, the casing 90 is arranged to straddle a diameter portion of the wafer W in the radial direction of the turntable 2 when the wafer W is positioned below the casing 90. For example, a distance between the inner wall face of the casing 90 at the center area C side and the edge of the wafer W may be arranged to be about 70 mm, and a distance between the inner wall face of the casing 90 on the outer periphery side of the turntable 2 and the edge of the wafer W may be arranged to be about 70 mm.

When the casing 90 is fit into the opening portion 11a, the flange portion 90a engages the lowermost step portion 11b of the step portions 11b. The step portion 11b of the ceiling plate 11 is hermetically connected to the casing 90 by the O-ring 11d corresponding to a sealing member. Further, a pressing member 91 in a frame-like shape formed so as to correspond to the opening portion 11a is used to press the flange portion 90a downward along its entire periphery. Then, the pressed pressing member 91 is secured to the ceiling plate 11 by, for example, a screw (not illustrated) to thereby hermetically seal the inner atmosphere of the vacuum chamber 1. At the time of hermetically sealing the inner atmosphere of the vacuum chamber 1, the distance h between the lower surface of the casing 90 and the upper surface of the wafer W on the turntable 2 may be 4-60 mm (30 mm in the above example). It is noted that FIG. 9 shows a perspective view of the casing 90 from the lower side.

As is shown in FIG. 8, a protruding portion 92 corresponding to a narrow space forming portion is arranged at the lower face of the casing 90. The protruding portion 92 is arranged to surround the process area P3 at the lower side of the casing 90 so that the atmosphere at the process area P3 may be maintained at a higher pressure than the atmospheric pressures at areas adjacent to the process area P3 in the peripheral direction of the turntable 2. That is, by arranging the protruding portion 92 at the lower face of the casing 90, a narrow space S1 (see FIGS. 6A-6B) is formed between the lower end portion of the protruding portion 92 and the turntable 2 so that gas supplied to the lower region of the casing 90 may be locked inside (prevented from being emitted) to cause the pressure at this region to be higher than that of the adjacent atmospheres. As is described in detail below, by arranging the protruding portion 92 at the lower region of the casing 90, gases at adjacent atmospheres may be prevented from mixing with one another, and the lower region of the casing 90 may act as a separating area D for separating these gases.

As shown in FIGS. 6A, 6B, 8, and 9, the protruding portion 92 protrudes in a downward direction from the lower face of the casing 90 towards the turntable 2 along the peripheral direction. Thus, the lower face (lower end portion) of the protruding portion 92 is positioned lower than the lower face of the casing 90 and the second ceiling surface 45. Referring to FIG. 6A, the distance d between the lower face of the protruding portion 92 and the upper face of the turntable 2 may be arranged to be 0.5-5 mm, for example. In the present example the distance d is 2 mm. The region surrounded by the inner peripheral face of the protruding portion 92, the lower face of the casing 90, and the upper face of the turntable 2 accommodates the first plasma generating gas nozzle 34. A section of the protruding portion 92 at the base end side of the first plasma generating gas nozzle 34 (the inner wall side of the vacuum chamber 1) is cutout into an arc-shape according to the outer shape of the first plasma generating gas nozzle 34 (see FIG. 9). It is noted that in FIG. 6A, the distance d is schematically shown larger than actual size and the antenna 83 is omitted.

Referring to FIG. 8, the protruding portion 92 is formed along the peripheral direction between the outer periphery of the process area P3 and the O-ring 11d, which seals an area between the ceiling plate 11 and the casing 90. In this way, the O-ring 11d may be isolated from the third process area P3 so that the O-ring 11d may not be directly exposed to plasma. That is, plasma diffused towards the O-ring 11d from the third process area P3 may be deactivated before reaching the O-ring 11d since the plasma passes through the lower side of the protruding portion 92 and may be attenuated during this time.

A Faraday shield 95 that is grounded is accommodated at the upper side of the casing 90. The shape of the Faraday shield 95 is arranged to be in substantial conformity with the internal shape of the casing 90 and is made of a conductive metallic plate having a thickness k of about 1 mm, for example. In this example, the Faraday shield 95 is made of a plate formed by plating a nickel (Ni) film and a gold (Au) film on a copper (Cu) plate or a Cu film. The Faraday shield 95 includes a horizontal surface 95a extending horizontally along a bottom surface of the casing 90 and a vertical surface 95b extending upward from the outer peripheral edge of the horizontal surface 95a. The Faraday shield 95 is arranged to be in a hexagonal shape when the Faraday shield 95 is viewed from the upper side of the Faraday shield 95 (a hexagonal shape in plan view).

Referring to FIG. 7, upper flanges of the Faraday shield 95 protrude horizontally in right and left directions with respect to the rotational center of the turntable 2. The upper flanges of the Faraday shield 95 form support portions 96. A frame 99 is provided between the Faraday shield 95 and the casing 90. The frame 99 is supported by the flange portion 90a at the center area C side of the casing 90 and at the outer peripheral side of the turntable 2. Therefore, when the Faraday shield 95 is accommodated inside the casing 90, the lower face of the Faraday shield 95 comes into contact with the upper face of the casing 90, and the supporting portion 96 is supported by the flange portion 90a of the casing 90 via the frame 99.

Referring to FIGS. 7 and 8, plural slits 97 are formed on the horizontal surface 95a of the Faraday shield 95. It is noted that the shape and layout of the slits 97 are described below in connection with the antenna 83 of the first plasma generating unit 81. An insulating plate 94 made of quartz with a thickness of about 2 mm is laminated on the horizontal surface 95a of the Faraday shield 95 to insulate the first plasma generating unit 81 from the Faraday shield 95.

The first plasma generating unit 81 is accommodated inside the Faraday shield 95 so as to face the inside of the vacuum chamber 1 (the wafer W on the turntable 2) via the casing 90, the Faraday shield 95, and the insulating plate 94. The first plasma generating unit 81 includes the antenna 83, which may be wound three times around a vertical axis to be shaped like an elongated octagon surrounding an area extending along the radial direction of the turntable 2. It is noted that a coolant passage for enabling the flow of cooling water is arranged inside the antenna 83, but this coolant passage is omitted in the drawings.

The ends of antenna 83 at the center area C side and the turntable 2 outer peripheral edge side are arranged to be positioned close to the inner peripheral face of the casing 90. In this way, plasma may be irradiated (supplied) over an entire range between the center area C side edge and the outer peripheral side edge when the wafer W is positioned below the first plasma generating unit 81. The antenna 83 is connected to a high frequency power source 85 with an output power of 5000 W and a frequency of 13.56 MHz, for example, via a matching box 84. Referring to FIGS. 1 and 3, a connection electrode 86 is provided to establish electrical connection between the antenna 83, the matching box 84, and the high frequency power source 85.

In the following, the slits 97 of the Faraday shield 95 are described. The slits 97 are arranged to prevent the electric field of the electromagnetic field generated by the antenna 83 from reaching the wafer W while prompting the magnetic field of the electromagnetic field to reach the wafer W. If the electric field reaches the wafer W, electric wiring formed inside the wafer W may be electrically damaged. On the other hand, since the Faraday shield 95 is made of a grounded metallic plate, the slits 97 are arranged so that the magnetic field may not be shielded in addition to the electric field. If a great opening portion is formed below the antenna 83, not only the magnetic field but also the electric field passes through the opening portion. Therefore, in order to shield the electric field but prompt the magnetic field to pass through the Faraday shield 95, the slits 97 are arranged to have the following dimensions and layout.

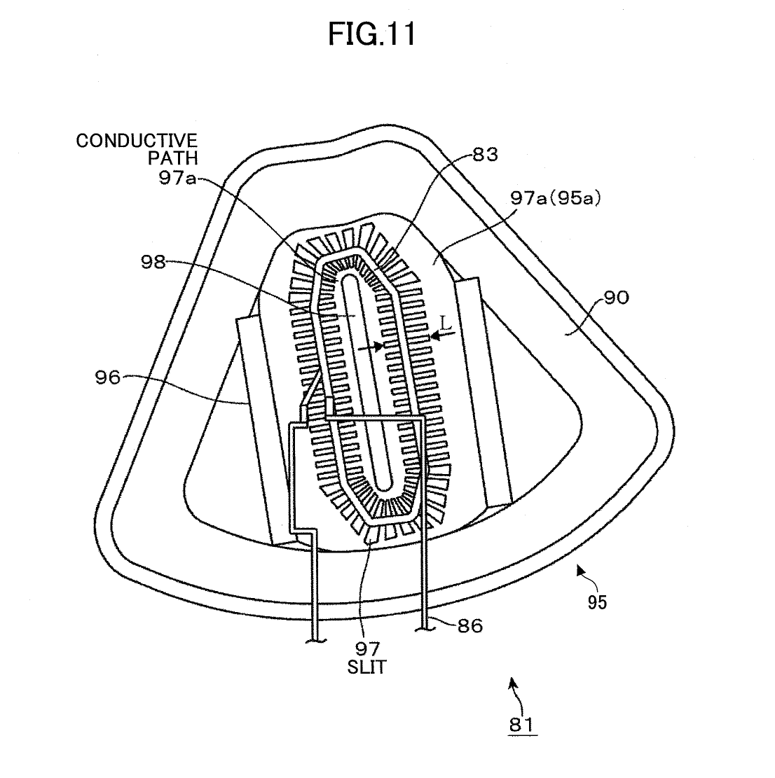

Referring to FIG. 11, the slits 97 are formed below the antenna 83 in directions perpendicular to the loop of the antenna 83 and are arranged along the loop below the antenna 83. Therefore, in a region where the antenna 83 extends along the radial direction of the turntable 2 (longitudinal direction of the antenna 83), the slits 97 are arranged in the shape of straight lines extending in the tangential direction of the turntable 2. Also, in a region where the antenna 83 extends along the tangential direction of the turntable 2, the slits 97 are arranged in the shape of straight lines extending in a direction from the rotational center of the turntable 2 to the outer edge of the turntable 2. In a region between the above two regions where the antenna 83 is bent, the slits 97 are arranged into the shape of straight lines that extend in a direction perpendicular to the extending direction of the antenna 83. In this way plural slits 97 are arranged along the extending direction of the antenna 83.

As is described above, the high frequency power source 85 with a frequency of 13.56 MHz (wavelength of 22 m) is connected to the antenna 83. Therefore, the slits 97 are designed to have a width 1/10000 or less of the wavelength. Referring to FIG. 10, the slits 97 have a width d1 of 1-6 mm (2 mm in this example), and a distance between the slits d2 is 2-8 mm (2 mm in this example). The slits 97 may be arranged to have a length L of 60 mm, for example, in a direction perpendicular to the loop of the antenna 83. Right and left ends along the length L of the slits 97 are positioned at about 30 mm from the loop of the antenna 83. That is, conductive paths 97a made of grounded conductive material that cover the opening ends of the slits 97 are arranged at the right and left side edges along the length L of the slits 97 along the peripheral direction.

An opening portion 98 is formed on the area surrounded by the conductive path 97a (the area surrounded by the slits 97) inside the antenna 83. Via the opening portion 98, light emission by plasma inside the vacuum chamber 1 can be visually checked or checked by a camera. It is noted that the first plasma generating gas nozzle 34 is arranged at the downstream side of the opening portion 98 with respect to the rotational direction of the turntable 2. Also, it is noted that in FIG. 3, the slits 97 are omitted and the region where the slits 97 are to be formed are indicated by dotted-dashed lines. In FIGS. 7 and 11, the slits 97 are not fully illustrated. The actual number of the slits 97 arranged along the antenna 83 may be about 150, for example.

Referring to FIGS. 2 and 3, the second plasma generating unit 82 is arranged at the upstream side of the first plasma generating unit 81 with respect to the rotational direction of the turntable 2. The second plasma generating unit 82 is spaced apart from the first plasma generating unit 81 and has a configuration substantially similar to that of the first plasma generating unit 81. That is, the second plasma generating unit 82 includes the antenna 83 and is arranged at the upper side the casing 90, the Faraday shield 95, and the insulating plate 94. As with the first plasma generating unit 81, the second plasma generating unit 82 has an antenna (second antenna) 83 that is connected to a high frequency power source (second high frequency power source) 85 with an output power of 5000 W and a frequency of 13.56 MHz, for example, via a matching box (second matching box) 84. In the second plasma generating unit 82, the second plasma generating gas nozzle 32 is arranged at the upstream side of the region where the slits 97 are formed with respect to the rotational direction of the turntable 2.

In the following, components of the vacuum chamber 1 are described.

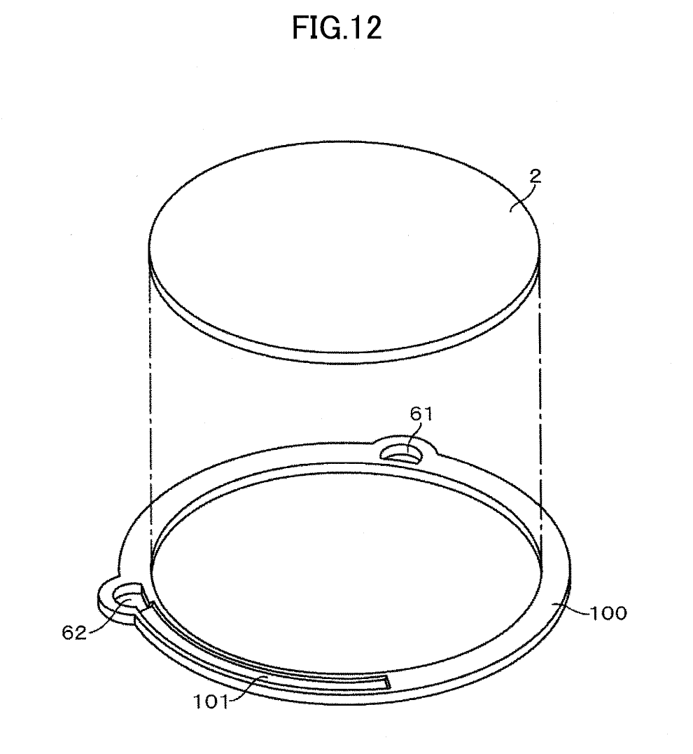

Referring to FIGS. 4 and 12, a side ring 100 corresponding to a cover is positioned slightly lower than the turntable 2 on an outer peripheral side of the turntable 2. The side ring 100 is provided to protect the inner wall of the vacuum chamber 1 from a fluorochemical cleaning gas that is supplied instead of the process gases when cleaning the film deposition apparatus, for example. If the side ring 100 is not provided, a ring-like recessed flow path for flowing exhaust gas or air may be formed between the outer periphery of the turntable 2 and the inner wall of the vacuum chamber 1. Therefore, the side ring 100 is arranged along this ring-like recessed flow path to prevent the inner wall surface from being exposed.

Two evacuation ports 61 and 62 are arranged on the upper face of the side ring 100. The evacuation ports 61 and 62 are separated in the peripheral direction of the side ring 100. That is, two exhaust routes may be formed below the ring-like recessed flow path. Actually, the evacuation ports 61, 62 corresponding to the two exhaust routes are formed in the side ring 100. The two evacuation ports include a first evacuation port 61 and a second evacuation port 62. The first evacuation port 61 is positioned between the first process gas nozzle 31 and the first plasma generating unit 81 towards a side closer to the first plasma generating unit 81. The second evacuation port 62 is positioned between the second plasma generating unit 82 and the separation area D towards a side closer to the second plasma generating unit 82. The first evacuation port 61 is for evacuating the Si-containing gas and the modification gas as well as the separation gas, and the second evacuation port 62 is for evacuating the ammonia gas and the separation gas. As is shown in FIG. 1, the first and second evacuation ports 61 and 62 may be connected to a vacuum pump 64 corresponding to a vacuum exhausting mechanism via evacuation pipes 63 and a pressure controller 65 such as a butterfly valve.

As is described above, since the casing 90 is formed from the center area C side to the outer edge side, gases such as the separation gas that flow through a region between the first and second plasma generating units 81 and 82 (region through which the wafer W is transported by a transport arm 10, which is described below) towards the evacuation ports 61 and 62 may be prevented by the casing 90 from flowing towards the evacuation ports 61 and 62. Accordingly, a grooved gas flow route 101 for prompting the flow of gas is formed on the upper face of the side ring 100 at the outer side of the casing 90 of the second plasma generating unit 82. The gas flow route 101 is arranged to enable evacuation of the gases through the above region while maintaining the gas separation function for preventing the Si-containing gas at the first plasma generating unit 81 from mixing with the ammonia gas at the second plasma generating unit 82. Specifically, referring to FIG. 4, the gas flow route 101 is shaped like an arc with a depth of about 30 mm, for example, and is arranged along the outer edge of the casing 90 of the second plasma generating unit 82 in the peripheral direction over a range between a position about 60 mm towards the first evacuation port 61 from the downstream side end of the casing 90 with respect to the rotational direction of the turntable 2 and a position of the second evacuation port 62. That is, the gas flow route 101 is arranged along the outer edge portion of the casing 90 of the second plasma generating unit 82 in plan view. Although not illustrated in the drawings, the side ring 100 may be coated with alumina or covered by a quartz cover in order to maintain corrosion resistance to fluorine gas.

Referring to FIG. 2, a ring-shaped protruding portion 5 is arranged at a center portion below the ceiling plate 11. The ring-shaped protruding portion 5 is continuously formed from a center area C side portion of the convex portion 4 and extends along the peripheral direction to form a substantially ring-like shape. The lower surface of the ring-shaped protrusion portion 5 has the same height as the lower surface of the convex portion 4 and the ceiling surface 44. The labyrinth structure 110 is arranged on the upper side of a core portion 21 towards the rotational center side of the turntable 2 from the ring-shaped protrusion portion 5. The labyrinth structure 110 prevents gases such as the Si-containing gas and the ammonia gas from mixing at the center area C. As can be appreciated from FIG. 1, the casing 90 is arranged to extend relatively close to the center area C, and the core portion 21 supporting the center portion of the turntable 2 is arranged closer to the rotational center of the turntable 2 so that an upper portion of the turntable 2 may be separated from the casing 90. With such a configuration, the process gases are more prone to mix with one another at the center area C compared to an outer edge area. Accordingly, the labyrinth structure 110 is arranged at the upper side of the core portion 21 to create an extended gas flow path for the gases to thereby prevent the gases from mixing with one another.

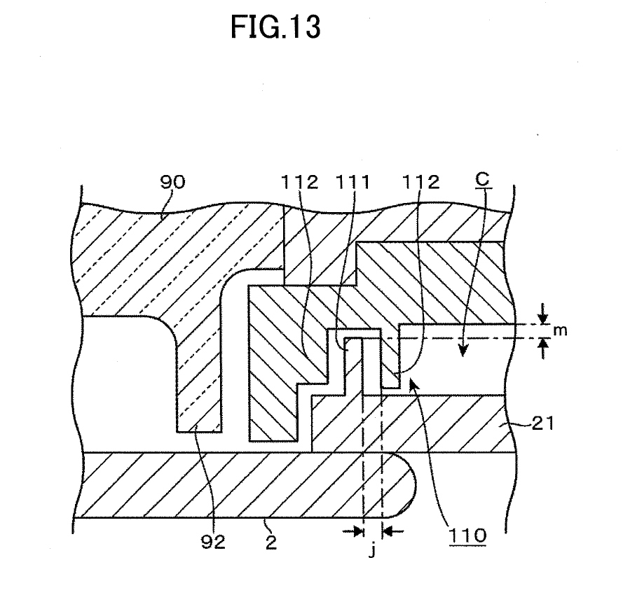

Referring to FIG. 13, the labyrinth structure 110 includes first walls 111 extending vertically from the turntable 2 toward the ceiling plate 11 and second walls 112 extending vertically from the ceiling plate 11 toward the turntable 2. The first walls 111 and the second walls 112 are formed along the peripheral direction respectively and alternately arranged in the radial directions of the turntable 2. In the illustrated example, the second wall 112, the first wall 111, and the second wall 112 are arranged in this order from the ring-shaped protrusion portion 5 to the center area C. The second wall 112 positioned towards the ring-shaped protrusion portion 5 forms a part of the ring-shaped protrusion portion 5. For example, the distance j between the first and second walls 111 and 112 may be 1 mm, a distance m between the first wall 111 and the ceiling plate 11 (a distance m between the second wall 112 and the core portion 21) may be 1 mm.

By arranging the labyrinth structure 110, when the Si-containing gas is discharged from the first process gas nozzle 31 and flows towards the center area C, the flow rate of the Si-containing gas may be reduced as it comes closer to the center area C and diffusion of the Si-containing gas may be prevented since the Si-containing gas has to flow through the first and second walls 111, 112. Therefore, before the Si-containing gas reaches the center area C, the Si-containing gas may be pushed back towards the process area P1 by the separation gas supplied to the center area C. It is noted that the ammonia gas and the argon gas flowing towards the center area C are similarly prevented from reaching the center area C by the labyrinth structure 110. In this way, process gases may be prevented from mixing with one another at the center area C.

Meanwhile, the N₂ gas supplied from the upper side of the center area C tends to swiftly spread toward the peripheral directions. However, the labyrinth structure 110 suppresses the flow rate of the N₂ gas while the N₂ gas flows through the first and second walls 111, 112. It is noted that the N₂ gas may even pass through the narrow space between the turntable 2 and the protruding portion 92. However, since the flow rate of the N₂ gas may be suppressed by the labyrinth structure 110, the N₂ gas may flow towards an area (e.g., area between the casing 90) that is wider than the narrow space. Therefore, the N₂ gas may be prevented from intruding into the lower side of the casing 90. Further, as described below, the area at the lower side of the casing 90 is arranged to have a higher pressure compared to the pressure of other areas inside the vacuum chamber 1. In this way, the N₂ gas may be prevented from intruding into other areas.

Referring to FIG. 1, a heater unit 7 corresponding to a heating mechanism is arranged within a space between the turntable 2 and a bottom portion 14 of the vacuum chamber 1. The wafer W on the turntable 2 may be heated via the turntable 2 to about 300° C., for example. In FIG. 1, a side of the heater unit 7 is covered by a cover member 71a, and an upper side of the heater unit 7 is covered by a cover member 7a. Purge gas supplying pipes 73 for purging areas of the heater units 7 are provided at plural positions under the heater units 7. The purge gas supplying pipes 73 are connected to the bottom portion 14 of the vacuum chamber 1 and arranged in a peripheral direction on the bottom portion 14.

Referring to FIG. 2 and FIG. 3, the transfer opening 15 is arranged at a side wall of the vacuum chamber 1. The transfer opening 15 is arranged to enable exchange of a wafer W between the turntable 2 and the transfer arm 10, which is an external unit. The transfer opening 15 can be opened or hermetically closed using a gate valve G. Further, a camera unit 10a for capturing images of the peripheral portion of the wafer W is arranged at the upper side of the ceiling plate 11 at a region where the transfer arm 10 moves back and forth with respect to the vacuum chamber 1. That is, by capturing images of the peripheral portion of the wafer W, the camera unit 10a may be used to determine whether a wafer W is placed on the transfer arm 10, or to detect positional deviations of the wafer W that is placed on the turntable 2 or the transfer arm 10, for example. Thus, the cameral unit 10a is arranged across a region between the respective casings 90 of the first plasma generating units 81 and the second plasma generating unit 82 in order to secure an adequate field of view in accordance with to the diameter of the wafer W.

Also, lift pins (not illustrated) for lifting the wafers W from the back surfaces of the wafers W and lifting mechanisms (not illustrated) are provided in the circular concave portions 24 of the turntable 2. The wafers W are delivered and received at a position corresponding to the transfer opening 15. Therefore, the lift pins penetrate the circular concave portions 24 from a lower surface of the turntable 2 to lift the wafers W to the position where the wafers W are delivered and received with the transfer arm 10.

Further, the film deposition apparatus includes a control unit 120 realized by a computer for controlling entire operations of the film deposition apparatus. Programs for performing processes such as the film deposition process and the modification process are stored in a memory of the control unit 120. The programs may describe process steps for executing operations of the film deposition apparatus, and may be installed into the control unit 120 via a memory unit 121, which may be a recording medium such as a hard disk, a compact disk, a magneto-optical disk, a memory card, or a flexible disk, for example.

In the following, operations of the film deposition apparatus according to the present embodiment are described.

First, the gate valve G is released. While the turntable 2 is intermittently rotated, five sheets of wafers W are mounted on the turntable 2 by the transfer arm 10 via the transfer opening 15.

The wafers W have undergone wiring embedding process using dry etching or chemical vapor deposition (CVD). Therefore, an electric wiring structure is formed inside the wafers W. Next, the gate valve G is closed to suction air inside the vacuum chamber 1 by a vacuum pump 64. While the turntable 2 is rotated in a clockwise direction, the wafers W are heated to be about 300° C. by the heater unit 7.

Then, the Si-containing gas is discharged from the first process gas nozzle 31 at 300 sccm, for example, and the ammonia gas is discharged from the second plasma generating gas nozzle 32 at 100 sccm, for example. Also, a mixed gas containing argon gas and hydrogen gas is discharged from the first plasma generating gas nozzle 34 at 1000 sccm, for example. Further, the separation gas is discharged from the separation gas nozzle 41 at 5000 sccm, for example, and nitrogen (N₂) gas is discharged from the separation gas supply pipe 51 and the purge gas supply pipes 72, 73 at predetermined flow rates. The inside of the vacuum chamber 1 is adjusted to have a predetermined processing pressure of about 400-500 Pa (500 Pa in the present example) by a pressure controller 65. Further, high-frequency power is supplied to the respective antennas 83 of the first plasma generating unit 81 and the second plasma generating unit 82 so that the power outputs of the antennas 83 may be 1500 W, for example.

At this point, the protruding portion 92 is arranged at the lower face side of the casing 90 along the peripheral direction and the lower end face of the protruding portion 92 is arranged to be positioned near the turntable 2. Also, as is described above, the gas flow rate of the modification gas at the first plasma generating gas nozzle 34 is arranged to be relatively high. Thus, the atmosphere pressure at the lower side of the casing 90 of the first plasma generating unit 81 may be about 10 Pa higher, for example, than the atmosphere pressure at the other regions within the vacuum chamber 1 (e.g., region where the transport arm 10 moves back and forth). In this way, gases at the upstream side and downstream side of the rotational direction of the turntable 2 with respect to the first plasma generating unit 81 may be prevented from flowing towards the lower side region of the casing 90. That is, the Si-containing gas and the ammonia gas may be prevented from mixing with each other via the process area P3. Also, the protruding portion 92 is similarly arranged at the casing 90 of the second plasma generating unit 82 so that the argon gas and the nitrogen gas may be prevented from mixing with each other via the process area P2.

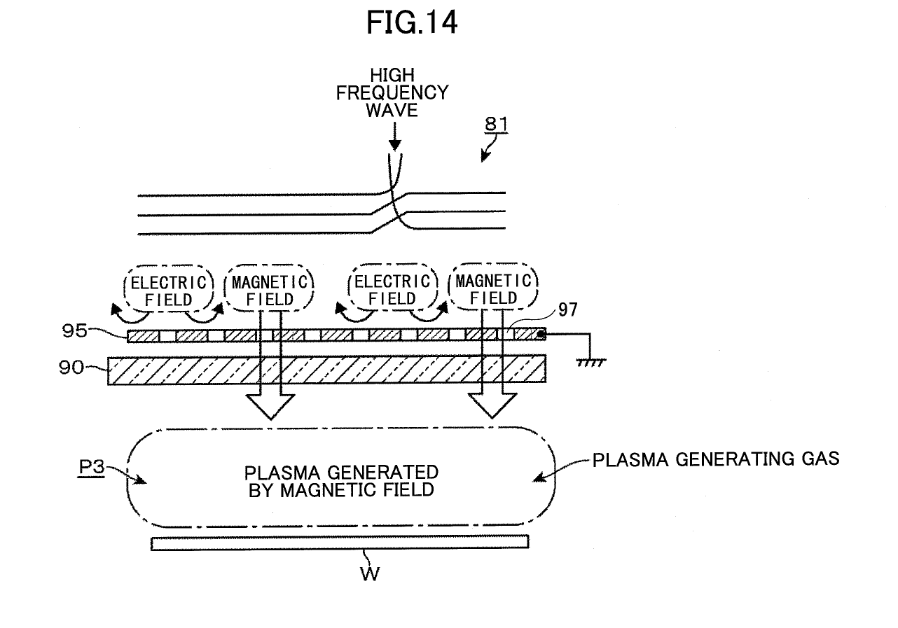

As is schematically illustrated in FIG. 14, the first and second plasma generating units 81, 82 each generate the electric field and the magnetic field by the high-frequency power supplied from their corresponding high frequency power sources 85. As described above, the Faraday shield 95 reflects, adsorbs, or attenuates the electric field to prevent the electric field from reaching inside the vacuum chamber 1 without shielding the magnetic field. That is, the electric field is shielded and the magnetic field is not shielded. Also, by arranging the conductive paths 97a at one end and the other end of the longitudinal direction of the slits 97, and arranging the vertical surface 95b at the side of the antenna 83, the electric field that tends to go around the one end to the other end of the slits 97 towards the wafer W may also be shielded. On the other hand, the magnetic field reaches the inside of the vacuum chamber 1 after passing the slits 97 of the Faraday shield 95 and the bottom surface of the casing 90.

In this way, the plasma generating gases discharged from the plasma generating gas nozzles 32, 34 may be activated by the magnetic fields that have passed through the slits 97 to thereby generate plasma such as ions and radicals. Specifically, plasma may be generated from ammonia gas at the process area P2, and plasma may be generated from argon gas and hydrogen gas at the process area P3, for example.

It is noted that argon gas plasma may tend to leak outside the casing 90 of the first plasma generating unit 81. However, since argon gas plasma has a very short life, the argon gas plasma may soon be deactivated to revert back to the original argon gas. Thus, argon gas and argon gas plasma may be prevented from reacting with other gases at regions at the turntable 2 rotational direction upstream side and downstream side of the casing 90 of the first plasma generating unit 81.

On the other hand, the life of ammonia gas plasma is longer than the life of argon gas plasma. Thus, the ammonia gas remains active while it passes the lower side of the casing 90 of the second plasma generating unit 82 and flows towards the turntable 2 rotational direction upstream side and downstream side of the casing 90. However, the separation area D is formed along the radial direction of the turntable 2 at the upstream side of the rotational direction of the turntable 2 with respect to the second plasma generating unit 82. Also, the first plasma generating unit 81 is arranged at the downstream side of the rotational direction of the turntable 2 with respect to the second plasma generating unit 82 via the back and forth moving region of the transfer arm 10. Thus, the ammonia gas plasma that has leaked outside the casing 90 of the second plasma generating unit 82 may be prevented from intruding unit the first process area P1 by the separation area D and the first plasma generating unit 81.

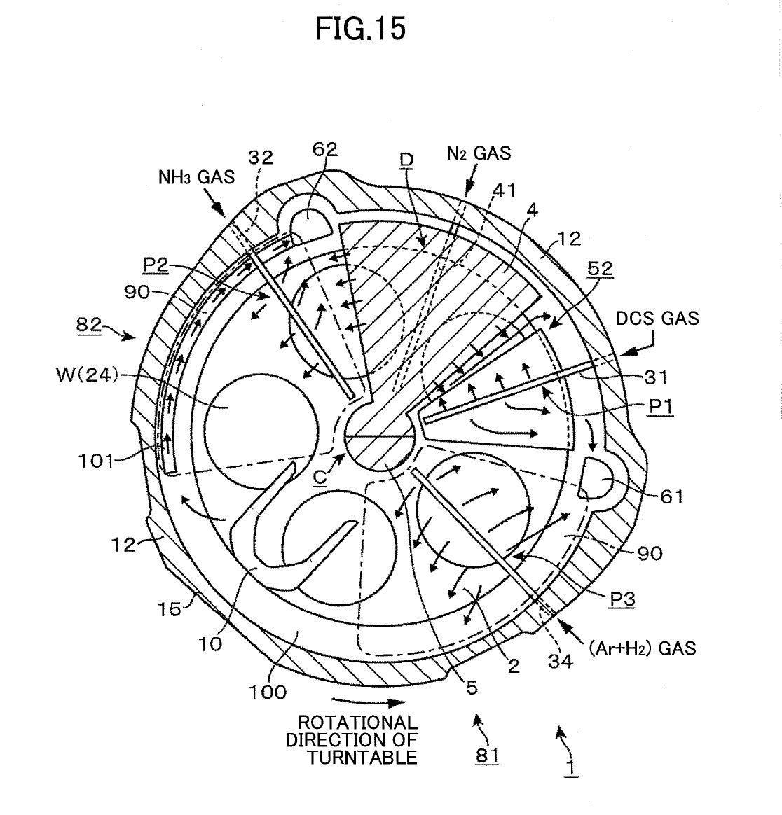

In this way, as is shown in FIGS. 6B and 15, the Si-containing gas and the ammonia gas may flow towards the evacuation ports 61, 62 to me evacuated while being prevented from mixing with one another by the separation area D and the first plasma generating unit 81.

Also, it is noted that gas flowing in the region between the casings 90 may be prevented from flowing by the casings 90. However, since the gas flow path 101 is formed at the side ring 100, the gas may flow through the gas flow path 101 towards the evacuation port 62 to be evacuated while avoiding the lower side region of the casings 90. It is noted that in FIG. 14, the antenna 83 is schematically illustrated, and the respective distances between the antenna 83, the Faraday shield 95, the casing 90, and the wafer W are schematically illustrated to be larger than actual scale.

Referring to FIGS. 3-4, when the turntable 2 is rotated, the Si-containing gas is adsorbed on the surface of the wafer W in the first process area P1. Further, components of the Si-containing gas adsorbed on the wafer W in the second process area P2 is nitrided by ammonia gas plasma to thereby form a reaction product on which one or more molecular layers of a silicon nitride (Si—N) film are formed as a thin film. At this time, impurities such as chlorine (Cl) and an organic substance may be contained in the silicon nitride film due to a residual radical contained in the Si-containing gas.

Then, a modification process is performed on the silicon nitride film by rotating the turntable 2 so that the plasma of the first plasma generating unit 81 comes into contact with the surface of the wafer W. Specifically, for example, the plasma crashes against the surface of the wafer W thereby causing the impurities to be discharged from the silicon nitride film as HCl or organic gas or causing elements contained in the silicon nitride film to be rearranged for obtaining a highly dense silicon nitride film. By continuing the rotation of the turntable 2, adsorption of the Si-containing gas on the surface of the wafer W, nitriding the components of the Si-containing gas adsorbed on the surface of the wafer W, and the plasma modification of the reaction product may be repetitively performed so that the reaction products are laminated to form the thin film. As is described above, although the electric wiring is formed inside the wafer W, the electric field may be shielded by the Faraday shield 95 provided between the plasma generating units 81, 82 and the wafer W. Therefore, electric damage to the electric wiring can be prevented.

According to an aspect of the present embodiment, the separation area D is arranged between the first process area P1 and the second process area P2 as viewed from the upstream side of the rotational direction of the turntable 2, and the modification area (third process area P3) is arranged between the second process area P2 and the first process area P1 as viewed from the upstream side of the rotational direction of the turntable 2 where the first plasma generating unit 81 modifies the reaction product on the wafer W. Further, the protruding portion 92 of the casing 90 is arranged to surround the third process area P3, and the atmospheric pressure within the third process area P3 is arranged to be higher than the atmospheric pressures of the areas adjacent to the third process area P3 with respect to the peripheral direction (i.e., areas outside the casing 90). In this way, a modification process may be performed on the reaction product on the wafer W at the process area P3 while preventing the process gases from mixing with one another. Accordingly, another separation area D may not have to be arranged between the second process area P2 and the first process area P1 as viewed from the upstream side of the rotational direction of the turntable 2 so that the size of the film deposition apparatus (vacuum chamber 1) may be reduced. That is, by having the third process area P3 act as the separation area D, one separation area D may be omitted from the film deposition apparatus while maintaining the process gas separation function upon performing the Si-containing gas adsorption process, the ammonia gas plasma nitriding process, and the reaction product plasma modification process each time the turntable 2 is rotated. In this way, accommodations may be made to alleviate the space restrictions for arranging the plasma generating units 81 and 82. Thus, an area for transferring the wafer W may be secured and space for arranging the camera unit 10a may be secured even in a small film deposition apparatus (vacuum chamber 1).

Also, since only one separating area D is needed in the present embodiment, the amount of separation gas used may be reduced compared to an apparatus having another separation area D. In turn, costs for operating the apparatus (gas costs) may be reduced and the size of the vacuum pump 64 may be reduced.

Also, since the Faraday shields 95 are provided respectively between the plasma generating units 81, 82 and the corresponding wafers W, the electric fields generated in the plasma generating units 81, 82 may be shielded. In this way, plasma processes may be performed while preventing electric damage to the internal electric wiring of the wafers W by the plasma. In turn, thin films having desirable film quality and electric characteristics may be swiftly obtained. Further, since two plasma generating units 81, 82 are provided, different types of plasma processes may be combined, for example. That is, by combining different types of plasma processes such as the plasma nitriding process of the Si-containing gas adsorbed on the surface of the wafer W and the plasma modification process of the reaction product on the wafer W described above, flexibility and versatility of the apparatus may be enhanced, for example.

Also, by providing the Faraday shield 95, damage (etching) to members made of quartz such as the casing 90 inflicted by plasma (electric field) may be prevented. In turn, the life of the quartz members may be increased and contamination may be prevented.

Further, since the casing 90 is provided, the plasma generating units 81, 82 may be arranged close to the wafer W on the turntable 2. Therefore, even in a high pressure atmosphere (a low degree of vacuum) for conducting a film deposition process, deactivation of ions and radicals inside plasma can be suppressed to thereby perform a desirable modification process. Further, since the protruding portion 92 is provided at the casing 90, the O-ring lid is not directly exposed to the second and third process areas P2, P3. Therefore, a fluorine component contained in the O-ring 11d may be prevented from being mixed into the wafer W, and the life of the O-ring 11d may be increased.

Further, since the plasma generating units 81, 82 are accommodated inside their corresponding casings 90, the plasma generating units 81, 82 may be arranged at regions exposed to the atmosphere (regions outside the vacuum chamber 1) so that maintenance of the plasma generating units 81, 82 may be facilitated.

It is noted that, since the plasma generating units 81, 82 are accommodated inside their corresponding casings 90, at the center area C, the end portions of the plasma generating units 81, 82 towards the rotational center of the turntable 2 may be distanced away from the rotational center of the turntable 2 by the side wall thickness of the casings 90. As a consequence, plasma may be prevented from reaching the end portion of the wafer W towards the center area C. On the other hand, if the casing 90 is arranged closer to the center area C so that the plasma may reach the end portion of the wafer W towards the center area C, the center area C is narrowed as described above. In this case, the process gases may be mixed with one another at the center area C. However, in the present embodiment, the labyrinth structure 110 is formed in the center area C to extend the flow passage. Therefore, process gases such as the Si-containing gas and the ammonium gas may be prevented from mixing with one another at the center area C while maintaining the wide plasma space along the radial direction of the turntable 2.

In the following, other examples of the film deposition apparatus are described.

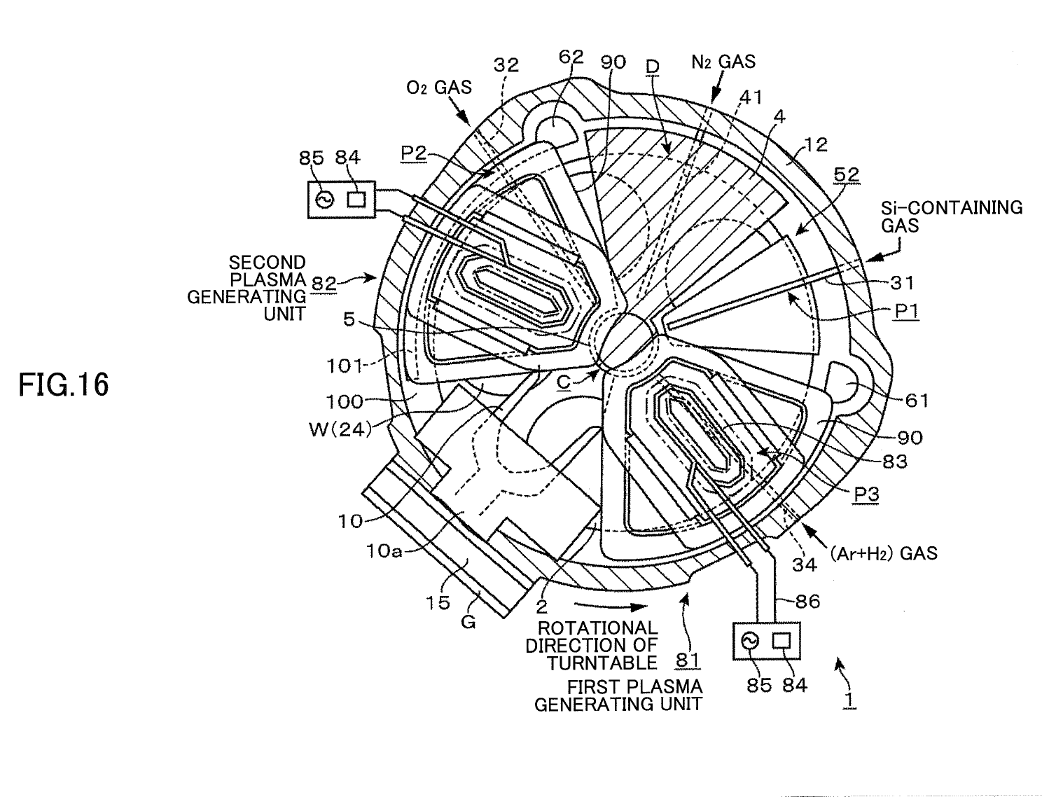

FIG. 16 illustrates an exemplary film deposition apparatus that uses BTBAS (bis(tertiary-butylaminosilane):SiH₂(NH—C(CH₃)₃)₂) gas as the first process gas instead DSC gas, and an oxygen (O₂) gas as the second process gas instead of the ammonia gas. In this film deposition apparatus, the oxygen gas is turned into plasma at the second plasma generating unit 82 to form a silicon oxide (Si—O) film as the reaction product.

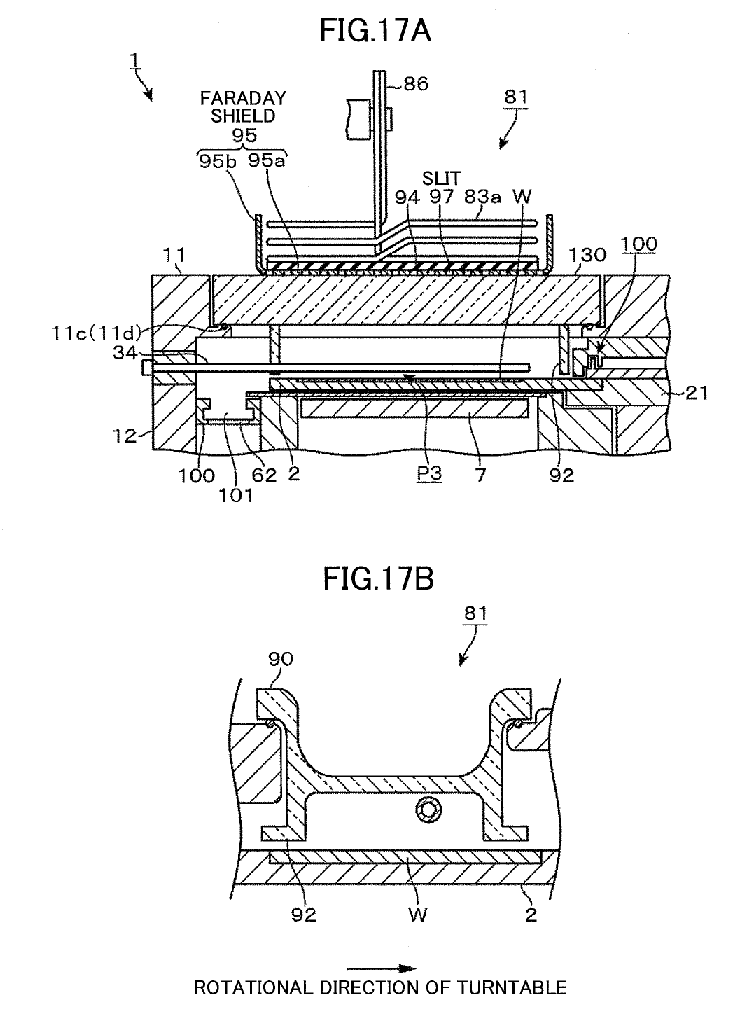

Also, to arrange the pressure of the process area P3 to be higher than the pressure at other areas of the vacuum chamber 1, the film deposition apparatus may be arranged to have a configuration as is shown in FIG. 17A, for example.

In FIG. 17A, the plasma generating unit 81 is arranged on the upper side of the ceiling plate 11, and a ceiling wall portion 130 corresponding to the ceiling plate 11 at the lower side of the plasma generating unit 81 is made of a material permeable to magnetic force such as quartz. Further, instead of arranging the protruding portion 92 at the lower face of the casing 90, the protruding portion 92 is arranged to extend downward from the lower face of the ceiling wall portion 130 towards the turntable 2 and along the peripheral direction to surround the third process area P3.

It is noted that the protruding portion 92 corresponding to the narrow space forming portion is not limited to the configurations described above that extend from the lower face of the casing 90 or the ceiling wall portion 130.

For example, as is shown in FIG. 17B, the protruding portion 92 extending toward the turntable from the lower side of the casing 90 or the ceiling wall portion 130 and along the peripheral direction may have a lower end portion arranged into a flange structure that extends outward.

Further, although the protruding portion 92 is arranged to surround the third process area P3 in the above examples, the protruding portion 92 may be arranged to have other configurations as long as it can block the gas from the upstream side and downstream side of the turntable 2 from flowing towards the third process area P3. For example, instead of arranging the protruding portion 92 to surround the third process area P3, the protruding portion 92 may be arranged to extend from the center area C side toward the outer edge side of the turntable 2 at the upstream side and downstream side of the turntable 2 as viewed from the third process area P3.

Further, instead of providing the protruding portion 92, the nozzle cover 52 may be arranged at the upper side of the first plasma generating gas nozzle 34. In this case, the upper face portion of the nozzle cover 52 forms the ceiling wall portion and the vertical faces of the nozzle cover 52 and the rectifying plate 54 form the narrow space forming portion. Also, the ceiling plate 11 at the lower side of the first plasma generating unit 81 is made of a material permeable to magnetic force as in the example shown in FIG. 17A.

Further, a protective film made of quartz, for example, may be arranged to cover the surfaces of the antenna 83 and the Faraday shield 95, and the antenna 83 and the Faraday shield 95 may be arranged in the vacuum chamber 1.

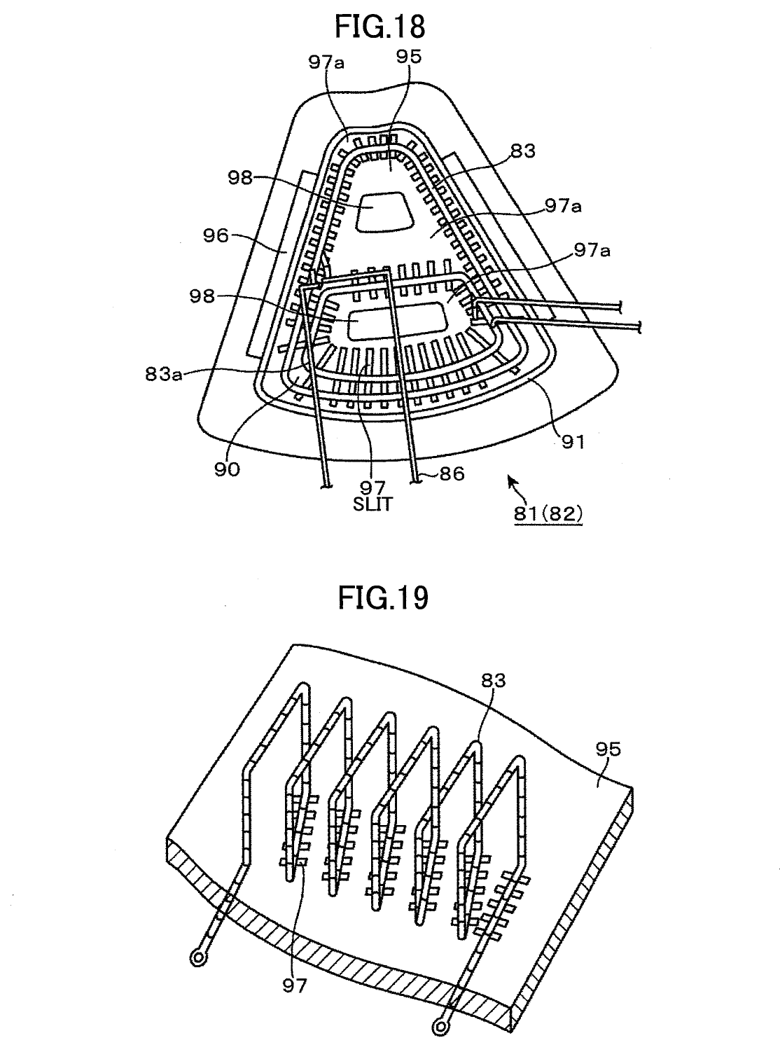

Further, referring to FIG. 18, the antenna 83 may be arranged into a fan-like shape in plan view according to the shape of the casing 90. Also, another antenna 83a may be arranged to face the outer periphery portion of the turntable 2.

Further, referring to FIG. 19, instead of winding the antenna 83 around a axis extending in up-down directions, the antenna 83 may be wound around an axis extending in the peripheral directions of the turntable 2.

The material of the Faraday shield 95 preferably has a low magnetic permeability to enable magnetic fields to pass through the Faraday shield 95. Specifically, the material may be silver (Ag), aluminum (Al) or the like, for example. As for the number of the slits 97 of the Faraday shield 95, when the number of slits 97 is too small, the magnetic field reaching inside the vacuum chamber 1 becomes small. On the other hand, when the number of the slits 97 of the Faraday shield 95 is too large, it becomes difficult to manufacture the Faraday shield 95. In a preferred embodiment, about 100 to 500 slits 97 are arranged over a 1 m-length of the antenna 83. Further, the ejection holes 33 of the plasma generating gas nozzles 32, 34 may be directed obliquely downward towards the upstream side of the rotational direction of the turntable 2 or the downstream side of the rotational direction of the turntable 2.

The modification gas used by the first plasma generating unit 81 to modify the reaction product is a gas that does not react with the first process gas and the second process gas and is capable of generating an active species for modifying the reaction product. Specifically, the mixed gas containing argon gas and hydrogen gas as described above may be used, or helium (He) gas and/or nitrogen gas may be used instead of or in addition to the argon gas and the hydrogen gas, for example. Further, to enable the first plasma generating unit 81 to realize the gas separation function as described above, the flow rate of the gas discharged from the first plasma generating gas nozzle 34 may be adjusted so that the pressure at the lower side of the casing 90 of the first plasma generating unit 81 may be about 5-30 Pa higher than the pressures of the atmospheres at the upstream side and downstream side of the rotational direction of the turntable 2 with respect to the casing 90 (pressure within the vacuum chamber 1 adjusted by the pressure controller 65). Specifically, the flow rate of the gas discharged from the first plasma generating gas nozzle 34 may be adjusted to be about 10-40% of the total flow rate of all the gases supplied to the vacuum chamber 1 (i.e., total flow rate of the nozzles 31, 32, 34, 41, 51, 72, and 73), and may be adjusted to 5-20 times the flow rate of the first process gas, or 1-5 times the flow rate of the second process gas, for example.

The material of the casing 90 may be an anti-plasma etching material such as alumina (Al₂O₃) or yttria instead of quartz. For example, the anti-plasma etching material may be coated on the surface of Pyrex (registered trademark) glass (heat-resistant glass manufactured by Corning Incorporated). That is, the casing 90 is made of a material that is permeable to magnetic fields (dielectric material) and has high durability against plasma.

Further, although the insulating plate 94 is arranged above the Faraday shield 95 to insulate the Faraday shield 95 from the antenna 83 in the above examples, the antenna 83 may be coated by an insulating material such as quartz instead of arranging the insulating plate 94, for example.

Further, although the plasma generating units 81, 82 are configured to generate inductively coupled plasma (ICP) by the antenna 83 in the above examples, the plasma generating unit 81, 82 may alternatively be configured to generate capacitively coupled plasma (CCP), for example.

Referring to FIG. 20, taking the second plasma generating unit 82 of the plasma generating units 81, 82 as an example, a pair of electrodes 141, 142 corresponding to parallel electrodes is arranged at the downstream side of the rotational direction of the turntable 2 with respect to the plasma generating gas nozzle 32. The electrodes 141, 142 are hermetically inserted from the side wall of the vacuum chamber 1. The electrodes 141, 142 are also connected to the matching box 84 and the high frequency power source 85. It is noted that a protective film made of quartz, for example, is formed over the surfaces of the electrodes 141, 142 in order to protect the electrodes 141, 142 from plasma.

The second plasma generating unit 82 with the above configuration may realize a plasma process by generating plasma from the plasma generating gas flowing in the region between the electrodes 141 and 142.

As is described above, the life of ammonia gas plasma is longer than the life of argon gas plasma. Thus, in the case of using argon gas plasma, the second plasma generating unit 82 for generating the argon plasma may be arranged at the base end side of the second plasma generating gas nozzle 32 (outside the vacuum chamber 1) instead of arranging the second plasma generating unit 82 on the upper side of the vacuum chamber 1 or inside the vacuum chamber 1.

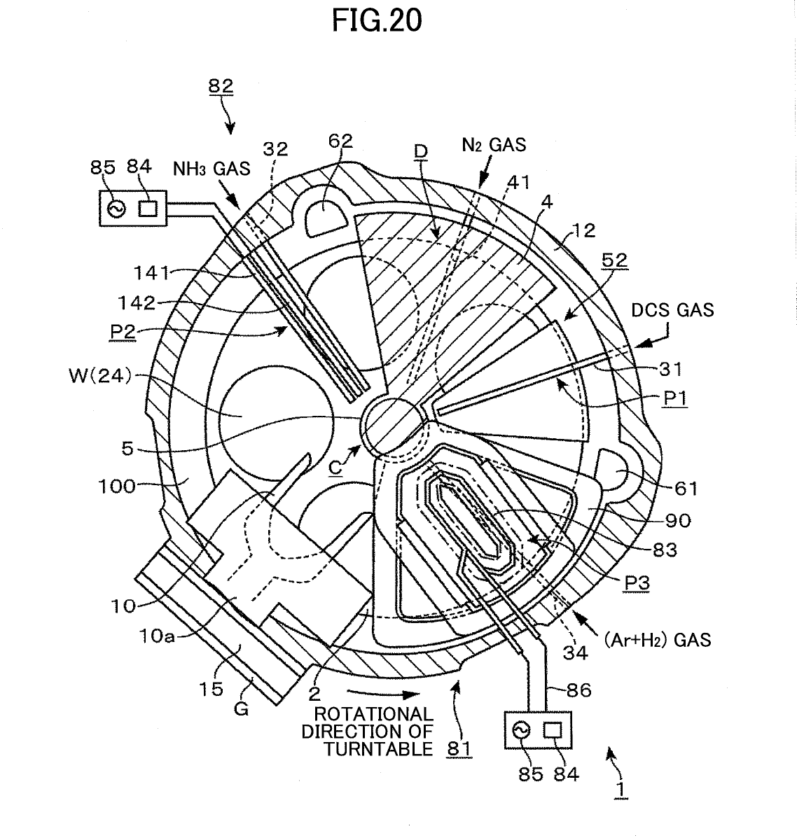

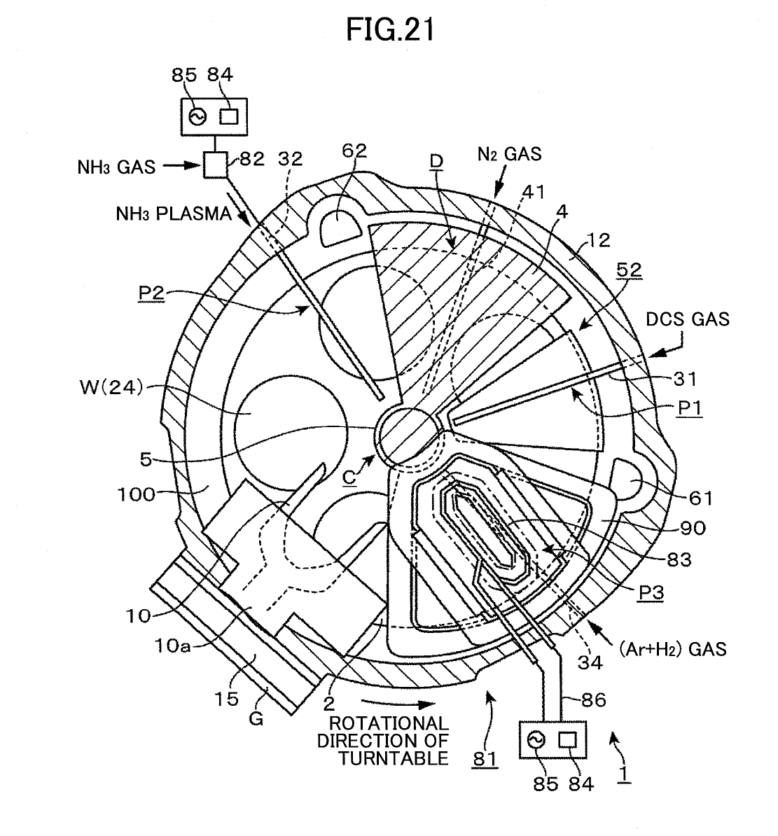

Specifically, referring to FIG. 21, for example, the second plasma generating unit 82 of the ICP type of the CCP type may be arranged between the second plasma generating gas nozzle 32 and the matching box 84 and the high frequency power source 85, and ammonia gas may be supplied to the second plasma generating unit 82.

Ammonia gas plasma generated by the second plasma generating unit 82 having the above configuration may flow through the second plasma generating gas nozzle 32 to come into contact with the wafer W within the vacuum chamber 1. In this way, a plasma nitriding process may be realized in a manner similar to the above examples.

Further, in activating the second process gas at the second process area P2, instead of turning the second process gas into plasma, the second process gas may be heated up to about 1000° C., for example.

Specifically, referring to FIG. 22, for example, a heating unit 143 extending along the radial direction of the turntable 2 and having a heater (not shown) embedded inside may be arranged along the second plasma generating gas nozzle 32. In FIG. 22 the heating unit 143 is connected to a power source 145 via a switch 144.

In the film deposition apparatus having the above configuration, the second process gas supplied to the vacuum chamber 1 from the second plasma generating gas nozzle 32 is activated by the heating unit 143 to generate an active species. In turn, the active species may cause a reaction (nitridation or oxidation) of the components of the Si-containing gas adsorbed to the wafer W in a manner similar to the above examples.

Also, since the life of the active species of ammonia gas is longer than the life of argon gas plasma, the heating unit 143 may similarly be arranged outside the vacuum chamber 1 instead of being arranged inside the vacuum chamber 1.

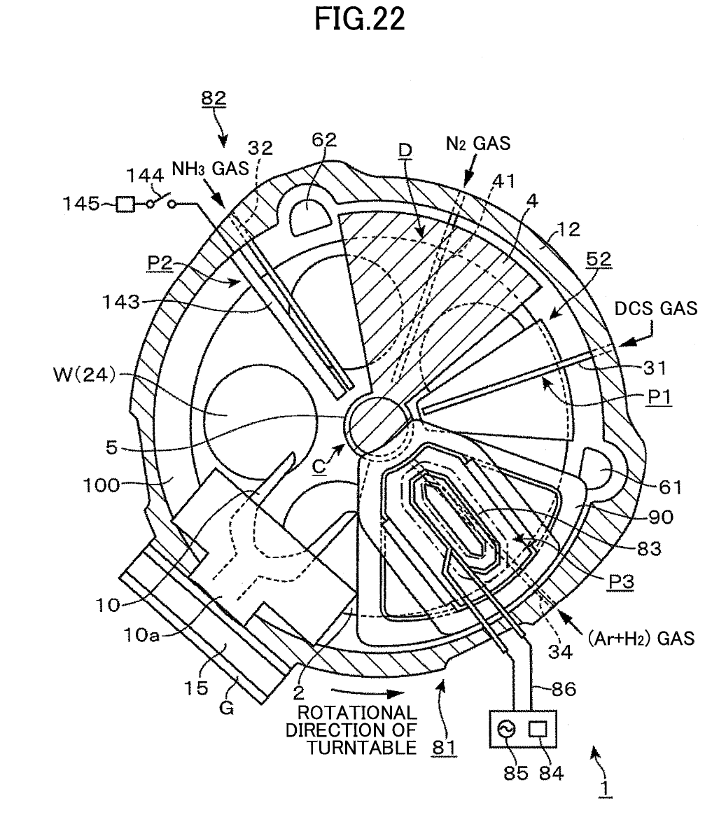

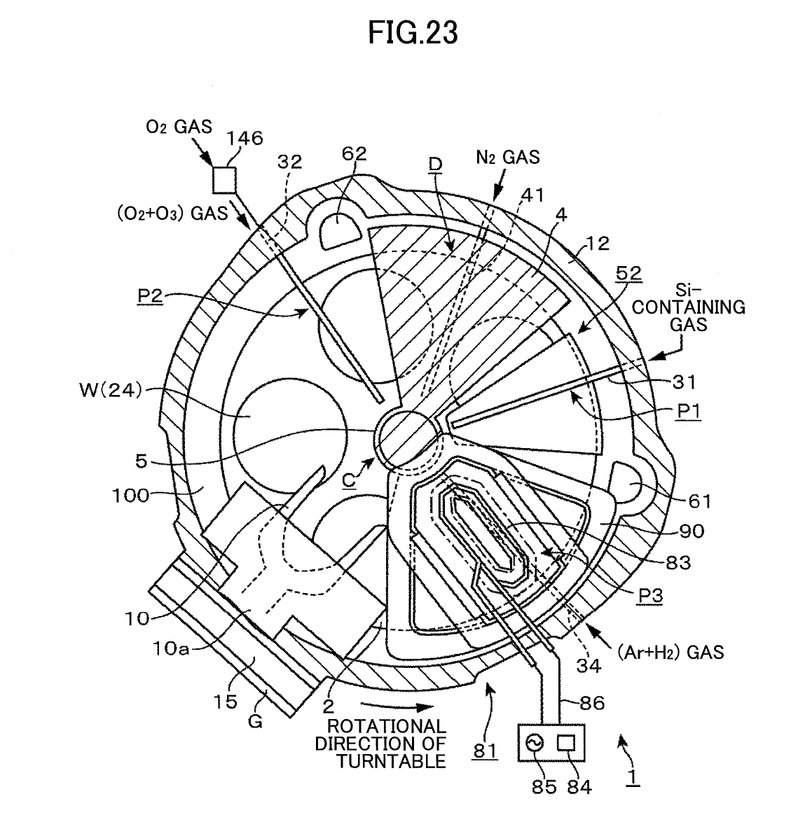

Further, referring to FIG. 23, in the case of using oxygen gas as the second process gas (i.e., in the case of forming a silicon oxide film), an ozonizer 146 for generating ozone (O₃) gas from the oxygen gas may be arranged outside the vacuum chamber 1, for example, so that an oxidation process may be performed on the wafer W using ozone gas.

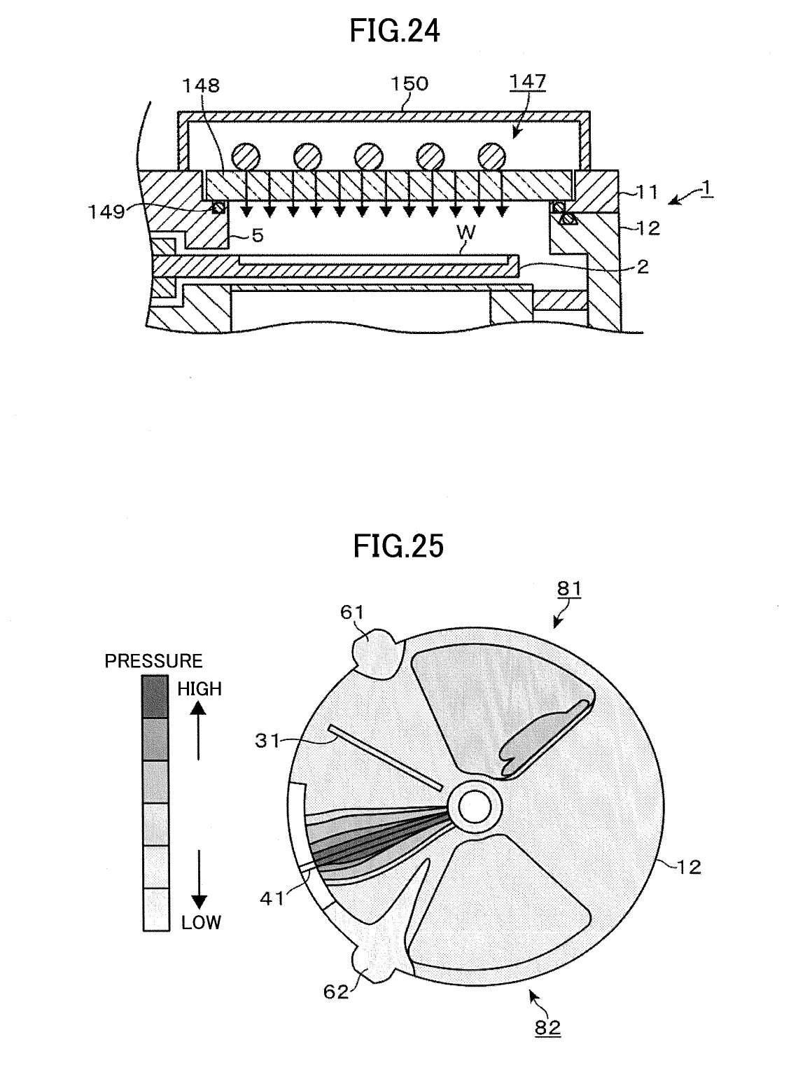

Further, referring to FIG. 24, in activating the second process gas, a lamp 147 for irradiating ultra violet (UV) rays on the wafer W may be used, for example. In FIG. 24, a transparent window 148, a sealing member 149 arranged between the transparent window 148 and the ceiling plate 11, and a housing 150 accommodating the lamp 147 are shown.

By irradiating UV rays on the second process gas using the lamp 147, the second process gas may be activated in a manner similar to the above examples, and the components of the Si-containing gas adsorbed in the wafer W may be nitrided or oxidized, for example.

### Simulation Examples

In the following, an exemplary simulation of the film deposition apparatus shown in FIG. 1 under the following simulation conditions is described. It is noted that in the present example, the first plasma generating gas nozzle 34 is arranged at the upstream side of the rotational direction of the turntable 2 with respect to the casing 90 of the first plasma generating unit 81, and the second plasma generating gas nozzle 32 is arranged at the downstream side of the rotational direction of the turntable 2 with respect to the casing 90 of the second plasma generating unit 82. Also, it is noted that the pressure distributions and mass density distributions described below represent values obtained 1 mm above the turntable 2.

(Simulation Conditions)

| First process gas (DCS gas) flow rate | 0.3 | slm |
|---|---|---|
| Second process gas (ammonia gas) flow | 5 | slm |
| rate | | |
| Modification gas (argon gas) flow rate | 15 | slm |
| Separation gas flow rate of separation | 5 | slm |
| gas nozzle 41 | | |
| Separation gas flow rate of separation | 1 | slm |
| gas supplying pipe 51 | | |
| Separation gas total flow rate of purge | 0.4 | slm |
| gas supplying pipes 72, 73 | | |
| Pressure within vacuum chamber 1 | 266.6 Pa | |
| | (2.0 Torr) | |
| Rotational speed of turntable 2 | 20 | rpm |
| Heating temperature of wafer W | 500° | C. |

FIG. 25 shows the pressure distribution within the vacuum chamber 1. As can be appreciated, in the first plasma generating unit 81, the pressure within the casing 90 is higher than the pressure at the region where the transfer arm 10 moves back and forth, for example.

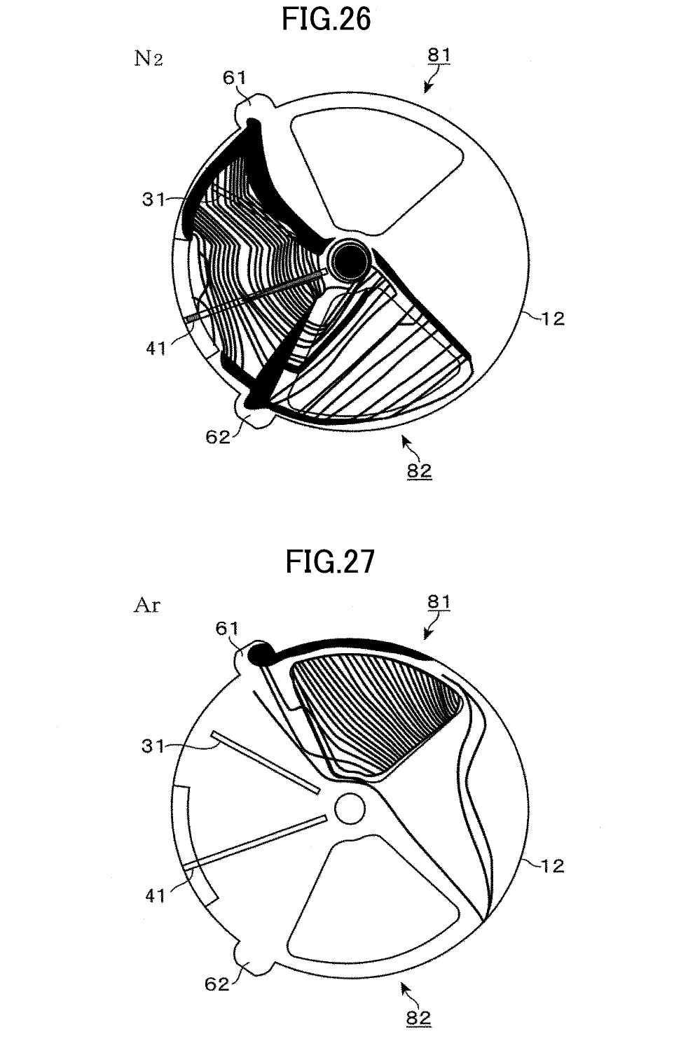

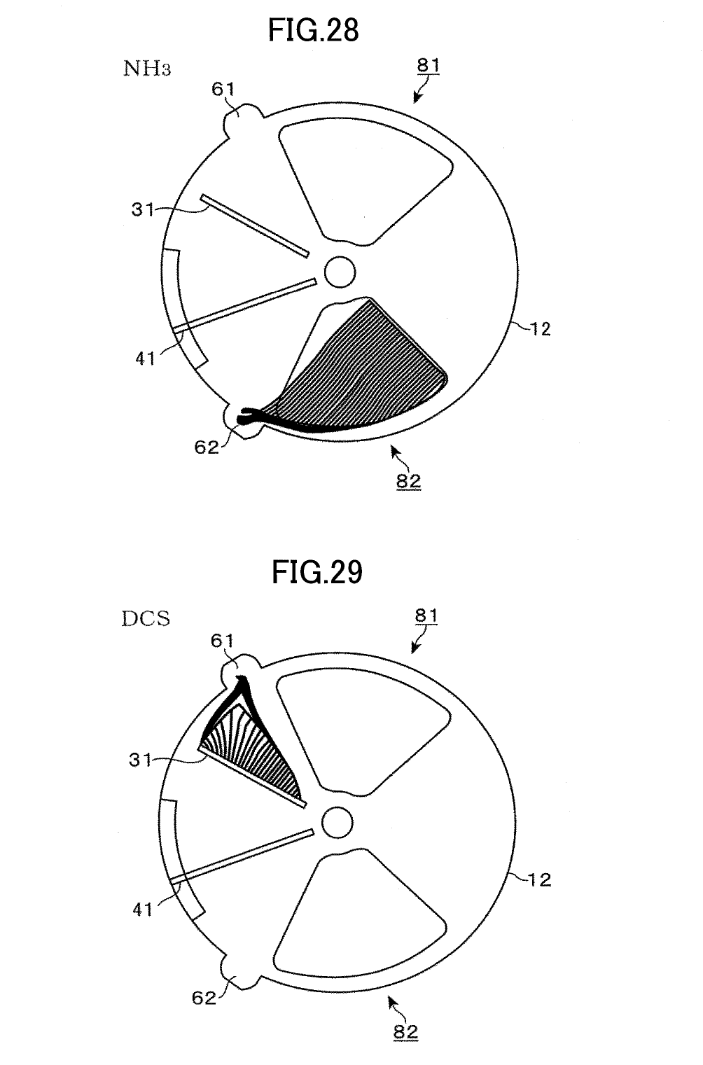

FIGS. 26-29 show trajectories of the various gases. Specifically, referring to FIG. 26, the nitrogen gas spreads in the left and right directions from the separation gas nozzle 41. Referring to FIG. 27, the argon gas spreads throughout the interior of the casing 90 but does not intrude into the first process area P1 that is adjacent to the third process area P3 or the second process area P2. Referring to FIG. 28, the ammonia gas similarly spreads throughout the interior of the casing 90 but does not intrude into the separation area D that is adjacent to the second process area P2 or the third process area P3. Referring to FIG. 29, the DCS gas flows along the rotational direction of the turntable 2 from the nozzle cover 52 to be evacuated through the evacuation port 61. In this way, the first process gas and the second process gas may be evacuated while being prevented from mixing with one another by the separation gas and the modification gas. Also, by arranging the protruding portion 92 at the casing 90, the ammonia gas and the argon gas may spread widely throughout the interior of the casing 90.

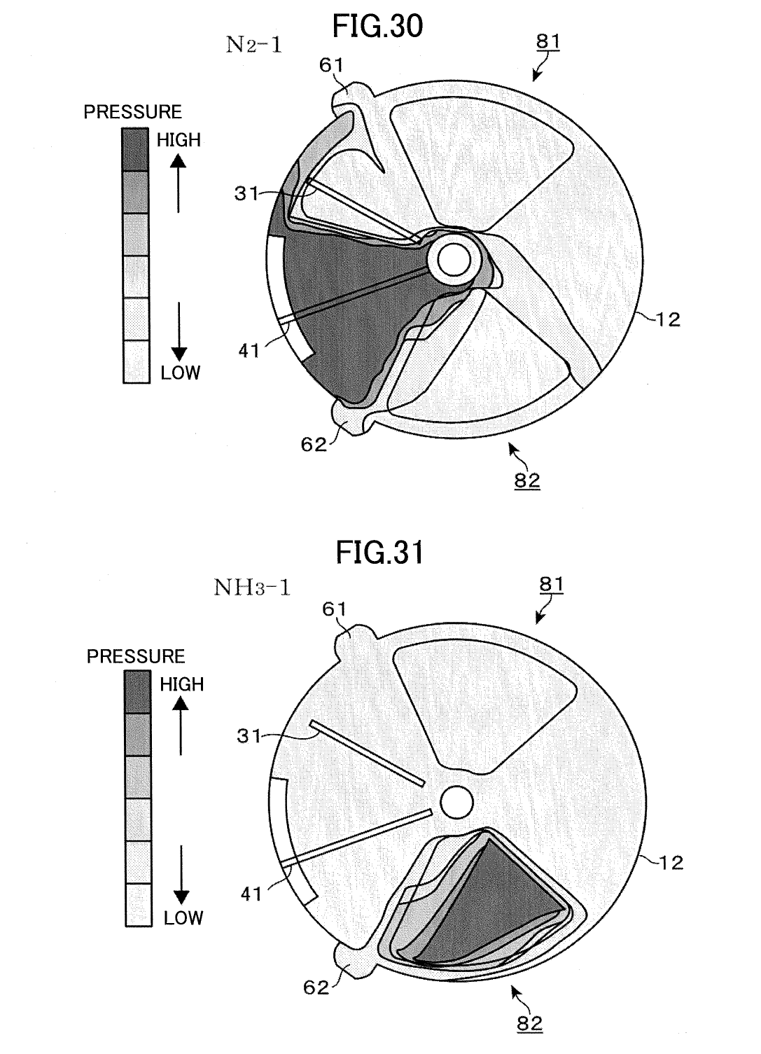

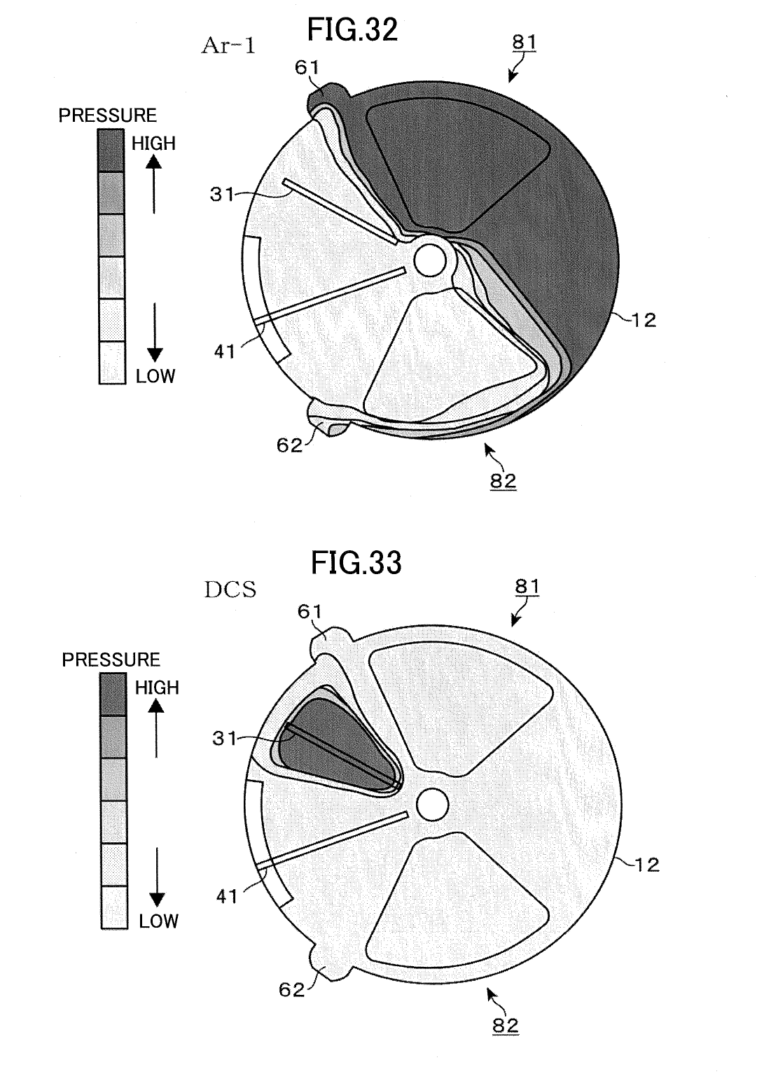

FIGS. 30-33 show simulation results of the mass density distributions of the various gases. Specifically, referring to FIG. 30, the nitrogen gas spreads in the left and right directions from the separation gas nozzle 41 in a manner similar to the nitrogen gas trajectory shown in FIG. 26. Referring to FIG. 31, the ammonia gas spreads throughout the interior of the casing 90. Referring to FIG. 32, argon gas flows spreads throughout the interior of the casing 90 of the first plasma generating unit 81 while avoiding the first process area P1 and the casing 90 of the second plasma generating unit 82 (second process area P2). Referring to FIG. 33, the DCS gas is distributed evenly at the lower side of the nozzle cover 52.

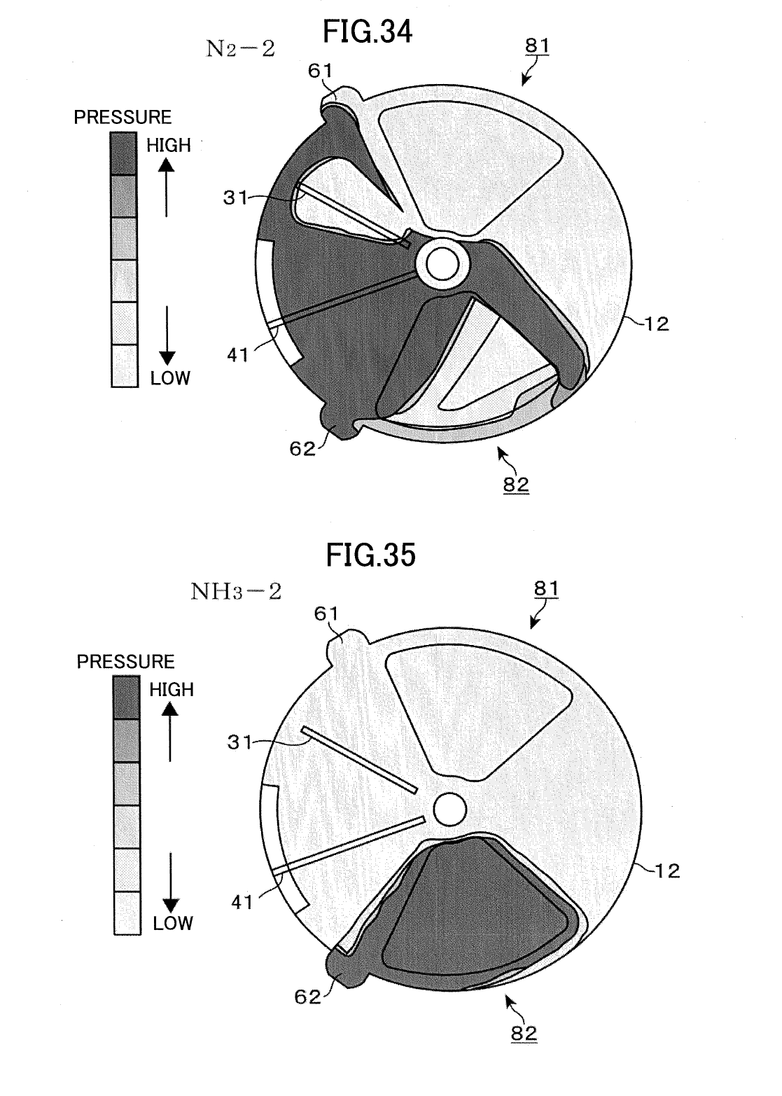

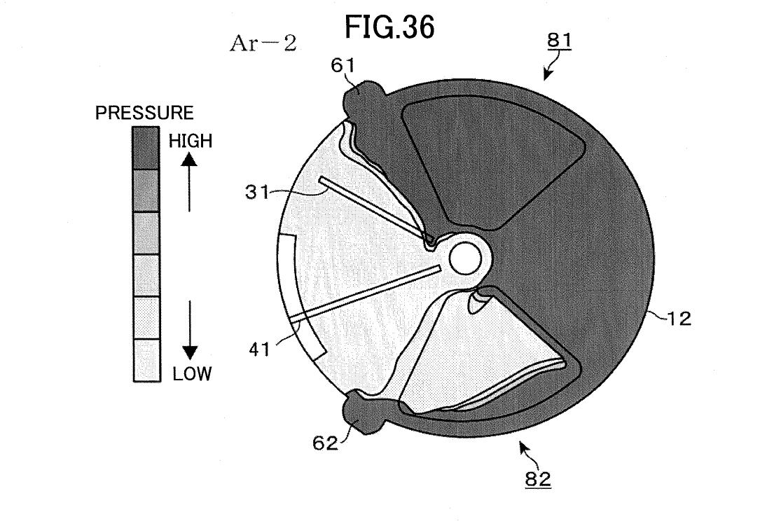

FIGS. 34-36 show simulation results of the mass density distribution of the separation gas, the ammonia gas, and the argon gas, focusing on the regions shown in FIGS. 30-32 where the mass density of the corresponding gas in the range of 0-10% (i.e., regions where the corresponding gas is distributed ever so slightly). Specifically, referring to FIG. 34, the nitrogen gas does not intrude into the casing 90 of the first plasma generating unit 81. Referring to FIG. 35, after the ammonia gas flows out towards the left and right sides of the casing 90 of the second plasma generating unit 82, it swiftly flows towards the evacuation port 62. Referring to FIG. 36, the argon gas does not intrude into the first process area P1 or the separation area D.

According to an aspect of the present embodiment, the separation area D is arranged between the first process area P1 and the second process area P2 as viewed from the upstream side of the rotational direction of the turntable 2, and the modification area (process area P3) is arranged between the second process area P2 and the first process area P1 as viewed from the upstream side of the rotational direction of the turntable 2 where the plasma generating unit 81 modifies a reaction product formed on a substrate (wafer W). Also, a ceiling wall portion is arranged at the upper side of the modification area, and the narrow space forming portion (protruding portion 92) is arranged between the modification area and areas adjacent to the modification area with respect to the peripheral direction of the turntable 2. Further, the pressure at the modification is arranged to be higher than the pressure at the adjacent areas in order to prevent the gases at the adjacent areas from intruding into the modification area. In this way, a modification process may be performed on the reaction product on the substrate at the modification area while preventing the first process gas and the second process gas from mixing with one another. Also, another separation area does not have to be provided between the second process area P2 and the first process area P1 as viewed from the upstream side of the rotational direction of the turntable 2 so that the size of the vacuum chamber 1 may be reduced.

Further, the present invention is not limited to these embodiments, and numerous variations and modifications may be made without departing from the scope of the present invention.

What is claimed is:

1. A film deposition apparatus that forms a film on a substrate by repeatedly performing a process of sequentially supplying a first process gas and a second process gas that react with one another inside a vacuum chamber, the film deposition apparatus comprising:
a turntable arranged inside the vacuum chamber and including a substrate mounting area that is formed on a surface of the turntable for mounting a substrate, the turntable being configured to rotate the substrate mounting area;
a first process area and a second process area that are separated from each other with respect to a peripheral direction of the turntable;
a first process gas supplying unit that supplies the first process gas that is adsorbed on a surface of the substrate to the first process area;
a second process gas supplying unit that supplies the second process gas to the second process area to cause a reaction with a component of the first process gas adsorbed on the surface of the substrate and form a reaction product on the substrate;
a separation area positioned between the first process area and the second process area as viewed from an upstream side of a rotational direction of the turntable;
a separation gas supplying unit that supplies a separation gas to the separation area to separate a first atmosphere of the first process area from a second atmosphere of the second process area;
a modification area for performing a modification process on the reaction product on the substrate using a first plasma, the modification area being positioned between the second process area and the first area as viewed from the upstream side of the rotational direction of the turntable and being arranged between the turntable and a ceiling wall portion that faces the surface of the turntable;
a modification gas supplying unit that supplies a modification gas that does not react with the first process gas and the second process gas to the modification area;
a first plasma generating unit that generates the first plasma from the modification gas;
a narrow space forming portion that has an end portion that defines a narrow space formed between the end portion and the turntable, the narrow space forming portion being positioned between the modification area and an adjacent area adjacent to the modification area with respect to the peripheral direction and having the end portion positioned lower than the ceiling wall portion and a ceiling face of the adjacent area to prevent a gas at the adjacent area from intruding into the modification area; wherein
a pressure at the modification area is arranged to be higher than a pressure at the adjacent area, and the modification area is arranged to act as a separation area for preventing the first process gas and the second process gas from mixing with one another.

2. The film deposition apparatus as claimed in claim 1, wherein
the first plasma generating unit includes
an antenna that is arranged to face the surface of the turntable and generate inductively coupled plasma from the modification gas; and
a Faraday shield intervening between the antenna and the modification area, the Faraday shield being made of a conductive plate that is grounded to prevent an electric field included in an electromagnetic field that is generated around the antenna from passing through the Faraday shield and including slits extending substantially perpendicular to an extending direction of the antenna to enable a magnetic field included in the electromagnetic field to reach the substrate.

3. The film deposition apparatus as claimed in claim 1, further comprising:
a second plasma generating unit that generates a second plasma from the second process gas.

4. The film deposition apparatus as claimed in claim 3, wherein
the second plasma generating unit includes
a second antenna that is arranged to face the surface of the turntable and generate inductively coupled plasma from the second process gas; and
a second Faraday shield intervening between the second antenna and the second process area, the second Faraday shield being made of a conductive plate that is grounded to prevent an electric field included in an electromagnetic field that is generated around the second antenna from passing through the second Faraday shield and including slits extending substantially perpendicular to an extending direction of the second antenna to enable a magnetic field included in the electromagnetic field to reach the substrate.

5. The film deposition apparatus as claimed in claim 2, further comprising:
a ceiling plate of the vacuum chamber that has an opening portion formed above the modification area for positioning the antenna below the ceiling plate; and
a casing made of dielectric material that is arranged between the antenna and the turntable, the casing being configured to fit into the opening portion and having a sealing member arranged to come into contact with an opening edge portion of the opening portion; wherein
the ceiling wall portion acts as a bottom face of the casing; and
the narrow space forming portion is arranged at the bottom face of the casing.

6. A film deposition method for forming a film on a substrate by repeatedly performing a process of sequentially supplying a first process gas and a second process gas that react with one another inside a vacuum chamber, the film deposition method comprising the steps of:
mounting a substrate on a surface of a turntable that is arranged inside the vacuum chamber, and rotating the substrate by rotating the turntable;
supplying a first process gas that is adsorbed on the surface of the substrate to a first process area;
supplying a second process gas to a second process area to cause a reaction with a component of the first process gas adsorbed on the surface of the substrate and form a reaction product on the substrate, the second process area being separated from the first process area with respect to a peripheral direction of the turntable;
supplying a separation gas to a separation area positioned between the first process area and the second process area as viewed from an upstream side of a rotational direction of the turntable, and separating a first atmosphere of the first process area from a second atmosphere of the second process area;
supplying a modification gas that does not react with the first process gas and the second process gas to a modification area for performing a modification process on the reaction product on the substrate using plasma, the modification area being positioned between the second process area and the first area as viewed from the upstream side of the rotational direction of the turntable and being arranged between the turntable and a ceiling wall portion that faces the surface of the turntable;
generating the plasma from the modification gas and modifying the reaction product on the substrate; and
preventing a gas at an adjacent area adjacent to the modification area with respect to the peripheral direction from intruding into the modification area by a narrow space forming portion that has an end portion that defines a narrow space formed between the end portion and the turntable, the narrow space forming portion being positioned between the modification area and the adjacent area and having the end portion positioned lower than the ceiling wall portion and a ceiling face of the adjacent area; wherein
a pressure at the modification area is arranged to be higher than a pressure at the adjacent area, and the modification area is arranged to act as a separation area for preventing the first process gas and the second process gas from mixing with one another.
